(19) United States
(12) Patent Application Publication
(10) Pub. No.: US 2009/0230391 A1
(43) Pub. Date: Sep. 17, 2009

(54) Resistance Storage Element and Method for Manufacturing the Same

(75) Inventor: Hideyuki Noshiro, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/400,272

(22) Filed: Mar. 9, 2009

(30) Foreign Application Priority Data
Mar. 11, 2008 (JP) 2008-61137

(51) Int. Cl. H01L 29/68; H01L 21/02; H01L 21/311

(52) U.S. Cl. 257/43; 438/104; 257/E21.214; 438/703; 438/652; 438/382; 257/E29.17; 257/E21.409; 257/E21.002

(57) ABSTRACT

A method for manufacturing a resistance storage element includes forming a lower electrode layer over a semiconductor substrate, forming a transition metal film over the lower electrode layer, forming an upper electrode layer over the transition metal film, and supplying oxygen contained in the lower electrode layer or the upper electrode layer to oxidize the transition metal film.

### CROSS-REFERENCE TO RELATED APPLICATIONS

This application is based upon and claims the benefit of priority from prior Japanese Patent Application No. 2008-061137, filed on Mar. 11, 2008, the entire contents of which are incorporated herein by reference.

### FIELD

The present invention relates to a resistance storage element that stores a plurality of resistance states showing different resistance values, and a method for manufacturing the same.

### BACKGROUND

As a new memory element, a non-volatile semiconductor storage device called a resistance random access memory (ReRAM) has received attention in recent years. An example of the ReRAM is a resistance storage element that has a plurality of resistance states showing different resistance values and changes its resistance state when externally receiving an electric stimulus. A ReRAM is used as a memory element by relating a high-resistance state and a low-resistance state of a resistance storage element, for example, to informational statuses “0” and “1”. A ReRAM characterized by high speed, large capacity, low power consumption, and other properties is a promising element.

A resistance storage element is formed by sandwiching a resistance storage material whose resistance state is changed by voltage application between a pair of electrodes: A resistance storage material that has been proposed is an oxide containing a transition metal.

FIG. 17 is a graph illustrating the current versus voltage characteristic of a proposed resistance storage element. As illustrated in FIG. 17, when the voltage applied to the resistance storage element in a high-resistance state is gradually increased, and the voltage becomes greater than a certain value (set voltage Vset), the resistance abruptly decreases and the resistance storage element transits to a low-resistance state. Such an action is typically called “set.” In a ReRAM, to prevent the resistance storage element and peripheral circuits from being damaged when a large current flows therethrough at the time of the set action, a selection transistor or any other suitable component is used to limit the current.

On the other hand, when the voltage applied to the resistance storage element in the low-resistance state is gradually increased to gradually increase the current flowing through the resistance storage element, and the current becomes greater than a certain value (reset current Ireset), the resistance abruptly increases and the resistance storage element transits to the high-resistance state. Such an action is typically called “reset.”

As described above, the resistance storage element in the high-resistance state transits to the low-resistance state when a voltage greater than or equal to the set voltage is applied, whereas the resistance storage element in the low-resistance state transits to the high-resistance state when a current greater than or equal to the reset current flows. The resistance of the resistance storage element in the low-resistance state is approximately several kΩ, whereas the resistance of the resistance storage element in the high-resistance state approximately ranges from several tens of kΩ to 1000 kΩ. Such actions can be used to control the resistance state of the resistance storage element.

Data can be read by measuring the magnitude of the current flowing through the resistance storage element when a given readout current is conducted through the resistance storage element.

The following are examples of related art of the present invention: Japanese Patent Laid-Open No. 2004-363604, Japanese Patent Laid-Open No. 2007-84935, Japanese Patent Laid-Open No. 2007-53125, Japanese Patent Laid-Open No. 10-149797, Japanese Patent Laid-Open No. 2005-191354, S. Seo et al., “Reproducible resistance switching in polycrystalline NiO films”, Applied Physics Letters, Volume 85, Number 23, p. 5655-5657 (2004), and S. Seo et al., “Conductivity switching characteristics and reset currents in NiO films”; Applied Physics Letters, 86, 093509 (2005).

There is a need to miniaturize a memory device using a resistance storage element as the packing density increases. There is also a need to reduce the voltage and current levels to operate the memory device.

### SUMMARY

Accordingly, it is an object in one aspect of the invention to provide a method for manufacturing a resistance storage element including forming a lower electrode layer over a semiconductor substrate, forming a transition metal film over the lower electrode layer, forming an upper electrode layer over the transition metal film, and supplying oxygen contained in the lower electrode layer or the upper electrode layer to oxidize the transition metal film.

The objects and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIGS. 1A and 1B are cross-sectional views illustrating a non-volatile semiconductor storage device according to a first embodiment of the present invention;

FIGS. 2A to 2L are process cross-sectional views illustrating a method for manufacturing the non-volatile semiconductor storage device according to the first embodiment of the present invention;

FIGS. 3A to 3C illustrate graphs illustrating the current versus voltage characteristic of the resistance storage element according to the first embodiment of the present embodiment;

FIGS. 4A and 4B illustrate cross-sectional views of a resistance storage element using a sputtered NiO film as a resistance storage layer and graphs illustrating the current versus voltage characteristic of the resistance storage element;

FIG. 5 is an electron micrograph of a cross-sectional structure of the resistance storage element using the sputtered NiO film as the resistance storage layer;

FIGS. 6A and 6B are cross-sectional views illustrating a non-volatile semiconductor storage device according to a second embodiment of the present invention;

FIGS. 7A to 7G are process cross-sectional views illustrating a method for manufacturing the non-volatile semiconductor storage device according to the second embodiment of the present invention;

FIGS. 8A and 8B are cross-sectional views illustrating a non-volatile semiconductor storage device according to a third embodiment of the present invention;

FIGS. 9A to 9G are process cross-sectional views illustrating a method for manufacturing the non-volatile semiconductor storage device according to the third embodiment of the present invention;

FIGS. 10A to 10D are process cross-sectional views illustrating a method for manufacturing a non-volatile semiconductor storage device according to a fourth embodiment of the present invention;

FIG. 11 illustrates graphs illustrating the current versus voltage characteristic of a resistance storage element according to the fourth embodiment of the present embodiment;

FIGS. 12A and 12B are cross-sectional views illustrating a non-volatile semiconductor storage device according to a fifth embodiment of the present invention;

FIGS. 13A to 13D are process cross-sectional views illustrating a method for manufacturing the non-volatile semiconductor storage device according to the fifth embodiment of the present invention;

FIGS. 14A and 14B are process cross-sectional views illustrating a method for manufacturing a non-volatile semiconductor storage device according to a sixth embodiment of the present invention;

FIGS. 15A to 15C are process cross-sectional views illustrating a method for manufacturing a non-volatile semiconductor storage device according to a seventh embodiment of the present invention;

FIGS. 16A to 16D are process cross-sectional views illustrating a method for manufacturing a non-volatile semiconductor storage device according to an eighth embodiment of the present invention; and

FIG. 17 is a graph illustrating the current versus voltage characteristic of a resistance storage element.

### DESCRIPTION OF THE PREFERRED EMBODIMENTS

Miniaturization of a resistance storage element desirably involves reducing the film thickness of an oxide material as a resistance storage material sandwiched between electrodes. Further, a large film thickness of the oxide material disadvantageously increases the voltage and current levels for operation. It is therefore desirable to reduce the film thickness of the oxide material also from the viewpoint of reducing the voltage and current levels for operation.

Simply forming a thin film of oxide material by sputtering or any other suitable method, however, results in degraded uniformity of the film thickness in some cases. The degraded uniformity of the film thickness leads to insufficient insulating performance between the electrodes, and it is therefore difficult to ensure characteristics for a resistance storage element.

### First Embodiment

A description will be made of a resistance storage element, a non-volatile semiconductor storage device using the resistance storage element, and a method for manufacturing the resistance storage element according to a first embodiment of the present invention.

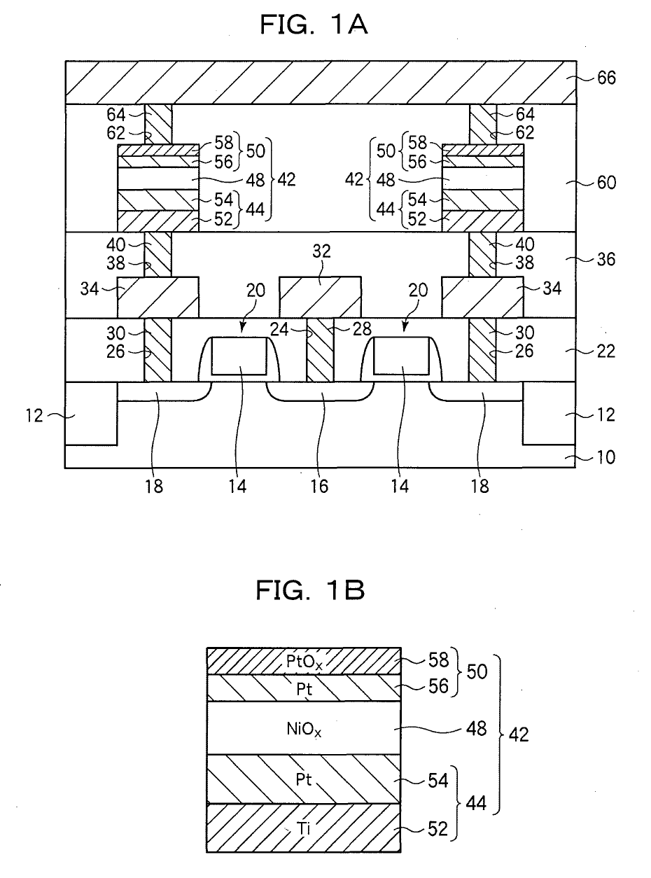

The resistance storage element and the non-volatile semiconductor storage device according to the present embodiment will be first described with reference to FIGS. 1A and 1B. FIG. 1A is a cross-sectional view illustrating the non-volatile semiconductor storage device according to the present embodiment. FIG. 1B is an enlarged view of only the resistance storage element.

As illustrated in FIGS. 1A and 1B, an element isolation area 12 that defines an element area is formed in a semiconductor substrate 10.

Gate electrodes 14 are formed on the semiconductor substrate 10 in which the element area has been defined, a gate insulating film interposed between each of the gate electrodes 14 and the semiconductor substrate 10. The gate electrodes 14 also function as word lines. The word lines 14 extend in the direction perpendicular to the plane of view in FIG. 1A.

Source/drain diffusion layers 16 and 18 are formed in the semiconductor substrate 10 on opposite sides of each of the gate electrodes 14.

One gate electrode 14 and source/drain diffusion layers 16 and 18 form a selection transistor 20. Two selection transistors 20 that share the source/drain diffusion layer 16 are formed in a single active area.

An interlayer insulating film 22 is formed on the semiconductor substrate 10 in which the selection transistors 20 have been formed.

A contact plug 28 connected to the source/drain diffusion layer 16 and contact plugs 30 connected to the source/drain diffusion layers 18 are embedded in the interlayer insulating film 22.

On the interlayer insulating film 22 in which the contact plugs 28 and 30 have been embedded are formed a source line (ground line) 32 electrically connected to the source/drain diffusion layer 16 (source terminal) via the contact plug 28 and relay wiring lines 34 electrically connected to the source/drain diffusion layers 18 (drain terminals) via the contact plugs 30. The source line 32 is formed parallel to the word lines 14 and extends in the direction perpendicular to the plane of view in FIG. 1A.

An interlayer insulating film 36 is formed on the interlayer insulating film 22 on which the source line 32 and the relay wiring lines 34 have been formed. Contact plugs 40 connected to the relay wiring lines 34 are embedded in the interlayer insulating film 36.

Resistance storage elements 42 are formed on the interlayer insulating film 36 in which the contact plugs 40 have been embedded. Each of the resistance storage elements 42 includes a lower electrode layer 44 electrically connected to the corresponding source/drain diffusion layer 18 via the corresponding contact plug 40, relay wiring line 34 and contact plug 30, a resistance storage layer 48 formed on the lower electrode layer 44, and an upper electrode layer 50 formed on the resistance storage layer 48.

The lower electrode layer 44 is a film obtained by stacking a close contact layer 52 and a noble metal film 54. The close contact layer 52 is made of, for example, titanium (Ti), and the noble metal film 54 is made of, for example, platinum (Pt).

The resistance storage layer 48 includes a transition metal oxide film made of nickel oxide (NiOₓ). The transition metal oxide film 48 is formed, as will be described later, by forming a noble metal oxide film 58, which forms the upper electrode layer 50, on a transition metal film 46 made of nickel (Ni) and then carrying out heat treatment to supply oxygen contained in the noble metal oxide film 58 to the transition metal film 46 so as to oxidize the transition metal film 46.

Since the transition metal oxide film 48 is formed by oxidation using oxygen contained in the noble metal oxide film 58, which forms the upper electrode layer 50, the oxygen concentration in the transition metal oxide film 48 has a gradient distribution. That is, the oxygen concentration in the transition metal oxide film 48 decreases in the direction from the upper electrode layer 50 toward the lower electrode layer 44.

The transition metal oxide film 48 is not directly deposited by sputtering or any other suitable method, but formed by oxidizing the transition metal film 46 using oxygen contained in the noble metal oxide film 58. The composition ratio of the oxygen of the transition metal oxide film 48 is thus lower than that in the stoichiometric composition. When an NiOₓ film is directly deposited by sputtering in a conventional manner, an NiOₓ film with a composition ratio of X=1, that is, the stoichiometric composition of Ni:O=1:1 (NiO film) is formed. It is therefore difficult to form an NiOₓ film having a composition different from the stoichiometric composition. In contrast, the present embodiment allows an NiOₓ film, for example, with a composition ratio of X=0.8 to 0.9, that is, a composition of Ni:O=1:0.8 to 0.9, to be formed as the transition metal oxide film 48, which forms the resistance storage layer.

The film thickness of the transition metal oxide film 48 is set to a relatively small value, for example, 10 nm or smaller, specifically, 1 to 10 nm.

The upper electrode layer 50 includes the noble metal oxide film 58 made of platinum oxide (PtOₓ) and a noble metal film 56 formed between the noble metal oxide film 58 and the transition metal oxide film 48, the noble metal film 56 made of Pt, which is the same type of noble metal that forms the noble metal oxide film 58. The noble metal film 56, as will be described later, is formed when the transition metal oxide film 48 is formed by supplying oxygen contained in the noble metal oxide film 58 to the transition metal film 46 to oxidize the transition metal film 46.

In the present embodiment, the transition metal oxide film 48 is formed by supplying oxygen contained in the noble metal oxide film 58 to the transition metal film 46 to oxidize the transition metal film 46. The present embodiment thus allows the formed transition metal oxide film 48 to be relatively thin, for example, 10 nm or thinner, and have good film thickness uniformity. A resistance storage element operable at low voltage and current levels can be thus provided.

An interlayer insulating film 60 is formed on the interlayer insulating film 36 on which the resistance storage elements 42 have been formed. Contact plugs 64 connected to the upper electrode layers 50 of the resistance storage elements 42 are embedded in the interlayer insulating film 60.

A bit line 66 electrically connected to the upper electrodes 50 of the resistance storage elements 42 via the contact plugs 64 is formed on the interlayer insulating film 60 in which the contact plugs 64 are embedded. The bit line 66 extends horizontally in the plane of view in FIG. 1A.

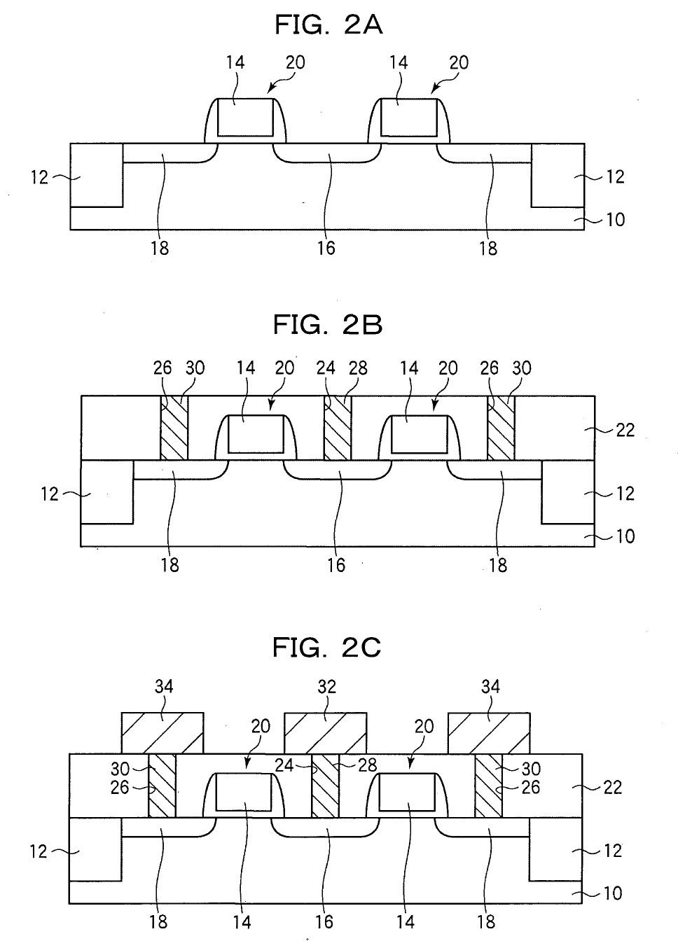

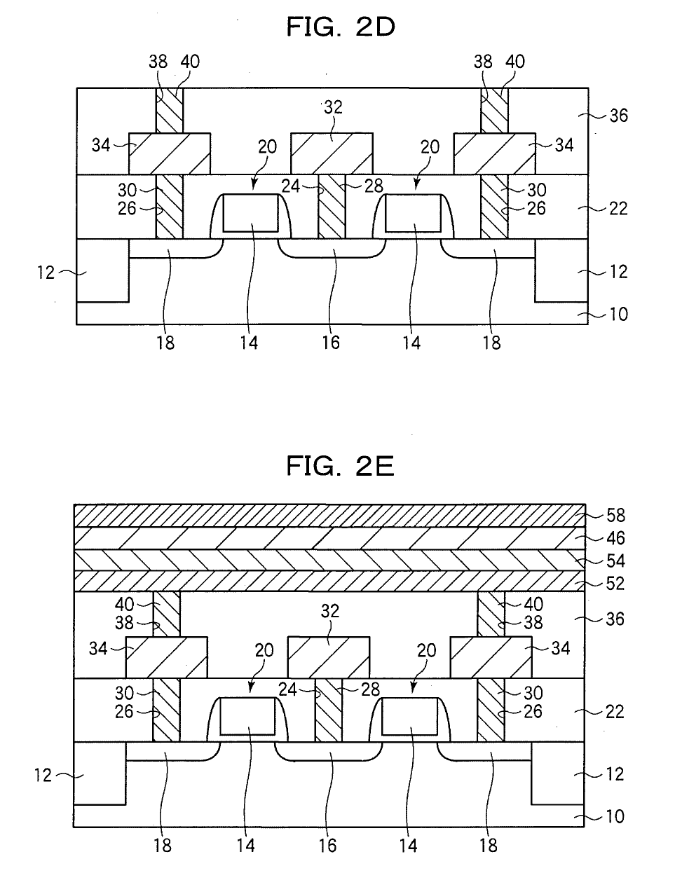

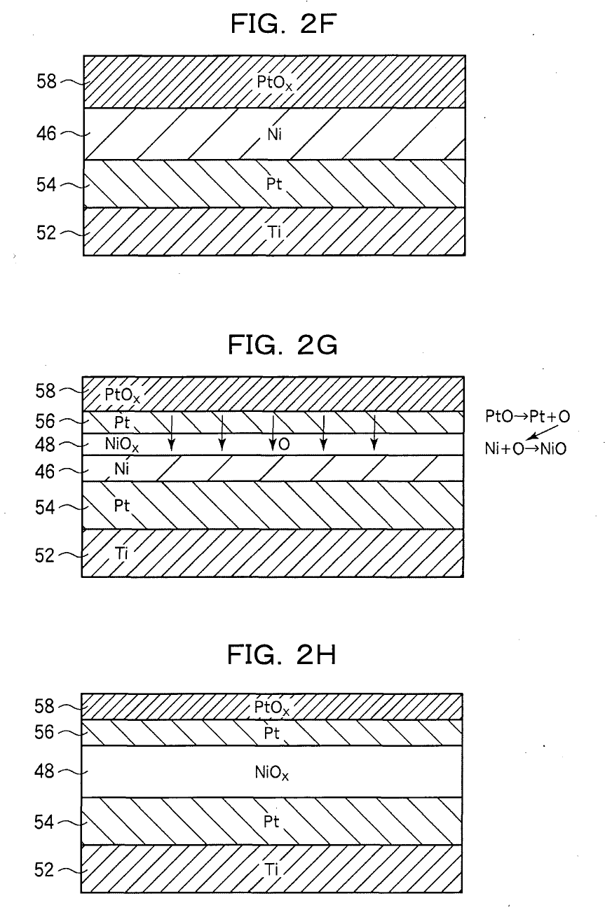

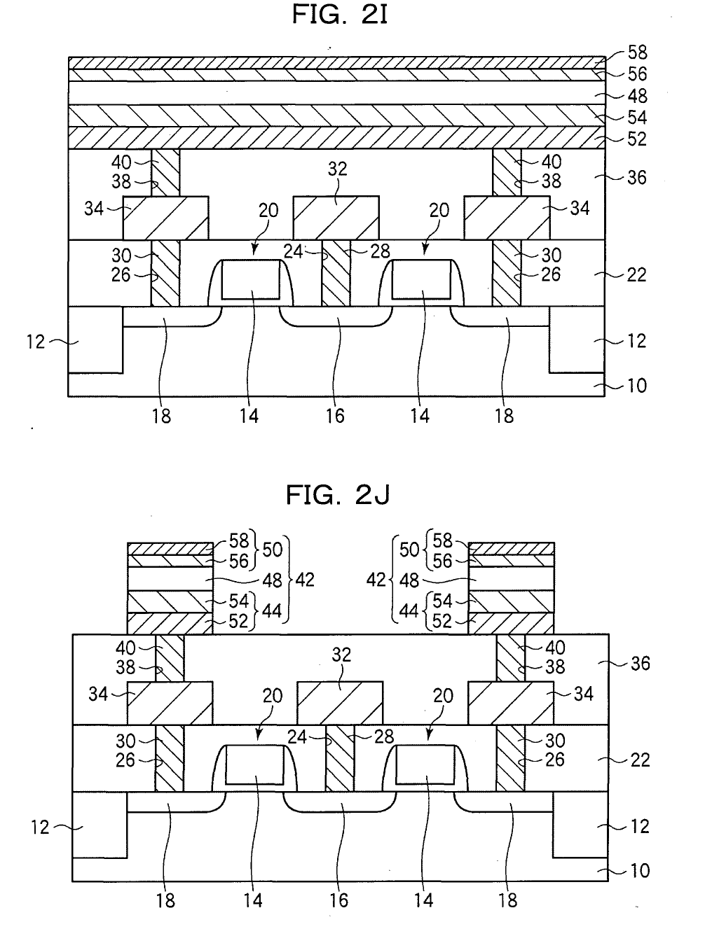

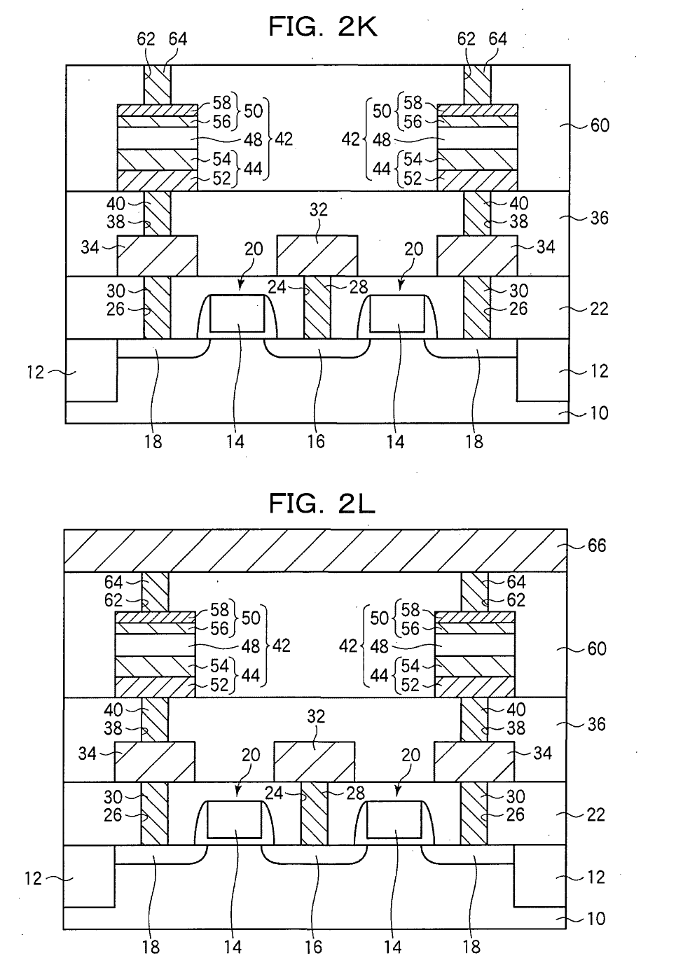

A method for manufacturing the resistance storage element and the non-volatile semiconductor storage device according to the present embodiment will be described below. FIGS. 2A to 2L are process cross-sectional views illustrating the method for manufacturing the resistance storage element and the non-volatile semiconductor storage device according to the present embodiment.

First, the shallow trench isolation (STI) or any other suitable method is used to form the element isolation area 12 that defines an element area in the semiconductor substrate 10. The semiconductor substrate 10 is, for example, a silicon substrate.

On the semiconductor substrate 10 are then formed the selection transistors 20, each of which including the corresponding gate electrode 14 and source/drain diffusion layers 16, 18, as in a method for manufacturing a typical MOS transistor (see FIG. 2A).

CVD (chemical vapor deposition) or any other suitable method is then used to deposit a silicon oxide film on the semiconductor substrate 10 on which the selection transistors 20 have been formed. Thereafter, the CMP or any other suitable method is used to polish the surface of the silicon oxide film to form the interlayer insulating film 22 including the silicon oxide film with a planarized surface.

Photolithography and dry etching are then used to form contact holes 24 and 26 in the interlayer insulating film 22 in such a way that they reach the source/drain diffusion layers 16 and 18.

CVD or any other suitable method is then used to deposit barrier metal and tungsten films. Thereafter, the conductive films are etched back to form the contact plugs 28 and 30 in the contact holes 24 and 26, the contact plugs 28 and 30 electrically connected to the source/drain diffusion layers 16 and 18 (see FIG. 2B).

CVD or any other suitable method is then used to deposit a conductive film on the interlayer insulating films 22 in which the contact plugs 28 and 30 have been embedded. Thereafter, photolithography and dry etching are used to pattern the conductive film to form the source line 32 electrically connected to the source/drain diffusion layer 16 via the contact plug 28 and the relay wiring lines 34 electrically connected to the source/drain diffusion layers 18 via the contact plugs 30 (see FIG. 2C).

CVD or any other suitable method is then used to deposit a silicon oxide film on the interlayer insulating film 22 on which the source line 32 and the relay wiring lines 34 have been formed. Thereafter, the CMP or any other suitable method is used to polish the surface of the silicon oxide film to form the interlayer insulating film 36 including the silicon oxide film with a planarized surface.

Photolithography and dry etching are then used to form contact holes 38 in the interlayer insulating film 36 in such a way that they reach the relay wiring lines 34.

CVD or any other suitable method is then used to deposit barrier metal and tungsten films. Thereafter, the conductive films are etched back to form the contact plugs 40 in the contact holes 38, the contact plugs 40 electrically connected to the source/drain diffusion layers 18 via the relay wiring lines 34 and the contact plugs 30 (see FIG. 2D).

Sputtering or any other suitable method is then used to deposit a Ti film having a film thickness of, for example, 10 nm on the interlayer insulating film 36 in which the contact plugs 40 have been embedded so as to form the close contact layer 52 including the Ti film. A titanium nitride (TiN) film may be deposited as the close contact layer 52 as well as the Ti film. The close contact layer 52 is provided to enhance the close contact property between the noble metal film 54 in the lower electrode layer 44 and the interlayer insulating film 36 including the silicon oxide film.

Sputtering or any other suitable method is then used to deposit a Pt film having a film thickness of, for example, 50 nm on the close contact layer 52 to form the noble metal film 54 including the Pt film.

Sputtering or any other suitable method is then used to deposit an Ni film having a film thickness of, for example, 8 nm on the noble metal film 54 to form the transition metal film 46 including the Ni film. The transition metal film 46 is formed in an atmosphere without oxygen and other oxidizing gases.

Sputtering or any other suitable method is then used to deposit a PtOₓ film having a film thickness of, for example, 10 nm on the transition metal film 46 to form the noble metal oxide film 58 formed of the PtOₓ film (see FIG. 2E). The noble metal oxide film 58 may be amorphous or crystalline. A case where the noble metal oxide film formed on the transition metal film 46 is crystallized will be described in a sixth embodiment.

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the noble metal oxide film 58 to be supplied to the transition metal film 46 so as to oxidize the entire transition metal film 46.

Specifically, for example, the following first to third heat treatment conditions can be used. That is, under a first heat treatment condition, a resistance heating electric furnace is used as the heat treatment apparatus at a heat treatment temperature of 400° C. for a heat treatment period of 30 minutes in an argon atmosphere as the heat treatment atmosphere at atmospheric pressure as the heat treatment pressure.

Under a second heat treatment condition, a low-pressure heating furnace is used as the heat treatment apparatus at a heat treatment temperature of 400° C. for a heat treatment period of 3 minutes in an argon atmosphere as the heat treatment atmosphere at 1 Pa as the heat treatment pressure. Under a third heat treatment condition, a rapid lamp heating apparatus (RTA apparatus) is used as the heat treatment apparatus at a heat treatment temperature of 400° C. for a heat treatment period of 1 minute in an argon/oxygen mixed gas atmosphere containing 5% of oxygen as the heat treatment atmosphere at atmospheric pressure as the heat treatment pressure. A heat treatment atmosphere containing oxygen or other oxidizing gases as in the case of the third heat treatment condition increases the rate at which the transition metal film 46 is oxidized, whereby the heat treatment period can be shortened.

Instead of oxidizing the entire transition metal film 46, part of the transition metal film 46 may be left between the transition metal oxide film 48 and the noble metal film 54. In this case, the heat treatment period may be shorter than those in the above cases. A case where part of the transition metal film 46 is left will be described in a second embodiment.

FIGS. 2F to 2H are enlarged views illustrating how the transition metal film 46 is oxidized in the present embodiment.

When heat treatment is carried out after the noble metal oxide film 58 has been formed on the transition metal film 46 as illustrated in FIG. 2F, oxygen contained in the noble metal oxide film 58 dissociates therefrom and is supplied to the transition metal film 46, as illustrated in FIG. 2G. The oxygen supplied from the noble metal oxide film 58 oxidizes the transition metal film 46 gradually from its surface to form the noble metal oxide film 48 in the transition metal film 46. As the noble metal oxide film 58 is reduced, the noble metal film 56 made of the noble metal that forms the noble metal oxide film 58 is formed in the lower portion of the noble metal oxide film 58.

As the heat treatment continues, the oxidation of the transition metal film 46 by the oxygen supplied from the noble metal oxide film 58 proceeds, and the entire transition metal film 46 is oxidized and the transition metal oxide film 48 is formed, as illustrated in FIG. 2H. The film thickness of the thus formed transition metal oxide film 48 is, for example, 10 nm or smaller, specifically, ranges from 1 to 10 nm. The noble metal film 56 formed in the lower portion of the noble metal oxide film 58 by the dissociation of the oxygen contained in the noble metal oxide film 58 has a film thickness of, for example, approximately 5 nm.

On the interlayer insulating film 36 are thus formed a stacked film including the close contact layer 52, the noble metal film 54, the transition metal oxide film 48, the noble metal film 56, and the noble metal oxide film 58 (see FIG. 2I).

As described above, in the present embodiment, the transition metal oxide film 48, which becomes the resistance storage layer of the resistance storage element 42, is formed by supplying oxygen contained in the noble metal oxide film 58 to the transition metal film 46 to oxidize the transition metal film 46. The present embodiment therefore allows the formation of the transition metal oxide film 48 having a relatively thin film thickness of, for example, 10 nm or smaller and good film thickness uniformity, whereby a resistance storage element operable at low voltage and current levels can be provided.

Further, in the transition metal oxide film 48 formed by the oxidation described above, the composition ratio of the oxygen thereof is lower than that in the stoichiometric composition. The thus composed transition metal oxide film 48 allows reactions in a forming process, the set action, and the reset action to more readily proceed than a transition metal oxide film having the stoichiometric composition does, whereby it is expected that the voltage and current levels for the operation of the resistance storage element can be reduced.

Photolithography and dry etching are then used to pattern the noble metal oxide film 58, the noble metal film 56, the transition metal oxide film 48, the noble metal film 54, and the close contact layer 52 to form the resistance storage elements 42, each of which having the lower electrode layer 44 including the stacked layer comprised of the close contact layer 52 and the noble metal film 54, the resistance storage layer 48 including the transition metal oxide film, and the upper electrode layer 50 including the noble metal film 56 and the noble metal oxide film 58 (see FIG. 2J).

CVD or any other suitable method is then used to deposit a silicon oxide film on the interlayer insulating film 36 on which the resistance storage elements 42 have been formed. Thereafter, the CMP or any other suitable method is used to polish the surface of the silicon oxide film to form the interlayer insulating film 60 formed of the silicon oxide film with a planarized surface.

Photolithography and dry etching are then used to form contact holes 62 in the interlayer insulating film 60 in such a way that they reach the upper electrode layers 50 of the resistance storage elements 42.

CVD or any other suitable method is then used to deposit barrier metal and tungsten films. Thereafter, the conductive films are etched back to form the contact plugs 64 in the contact holes 62, the contact plugs 64 connected to the upper electrode layers 50 of the resistance storage elements 42 (see FIG. 2K).

A conductive film is then deposited on the interlayer insulating film 60 in which the contact plugs 64 have been embedded. Thereafter, photolithography and dry etching are used to pattern the conductive film so as to form the bit line 66 electrically connected to the upper electrode layers 50 of the resistance storage elements 42 via the contact plugs 64 (see FIG. 2L).

An overlying wiring line layer and other layers are then formed. The non-volatile semiconductor storage device is thus completed.

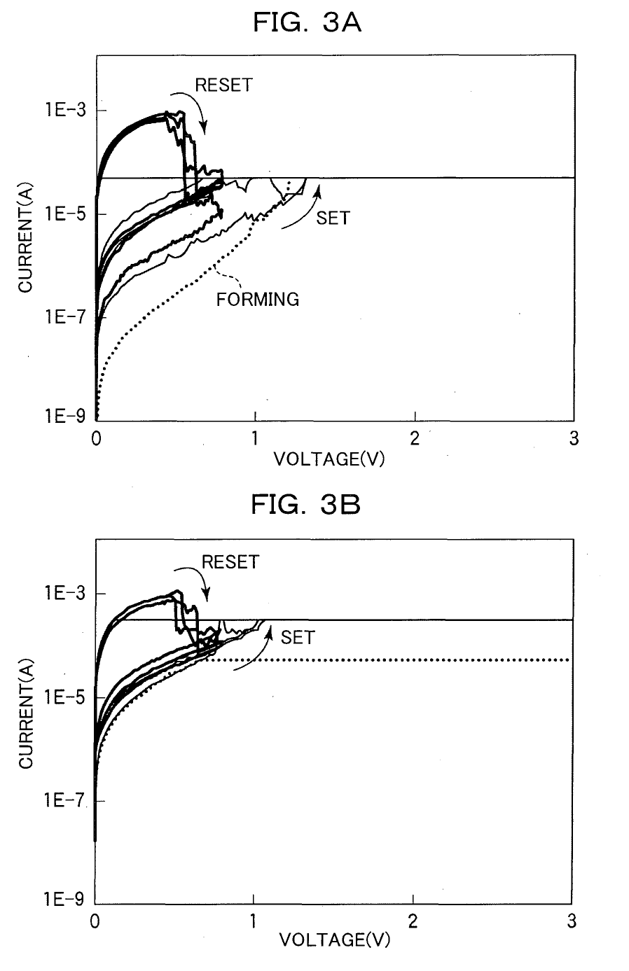

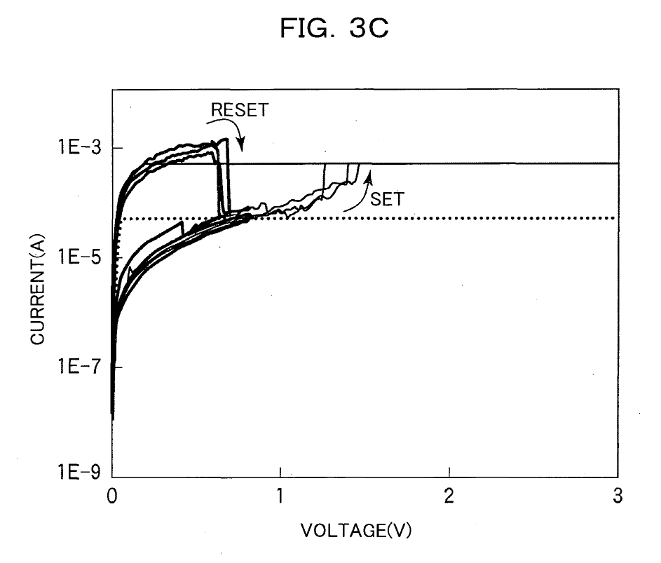

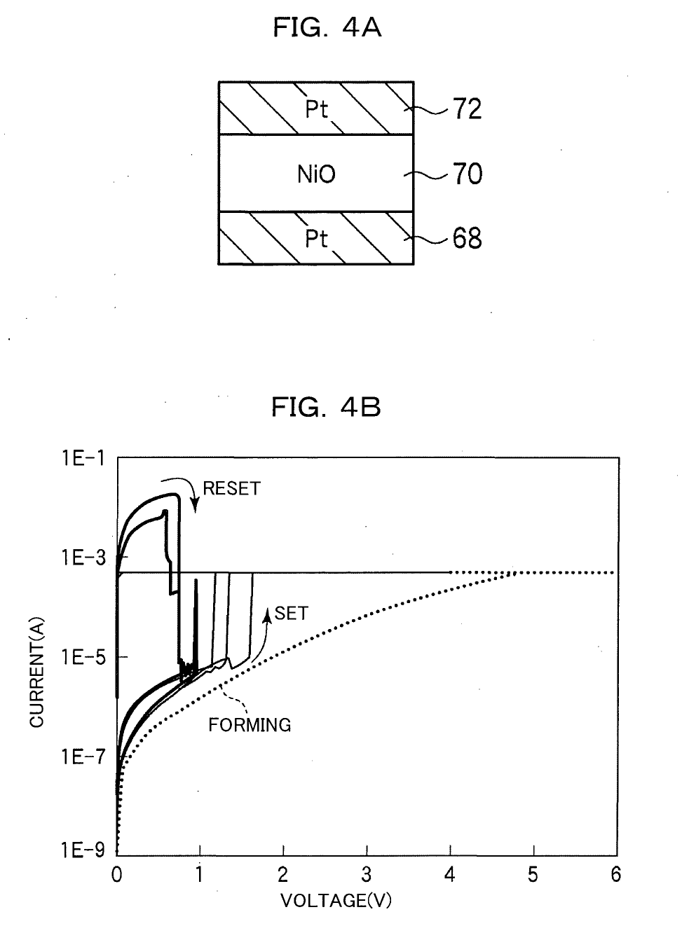

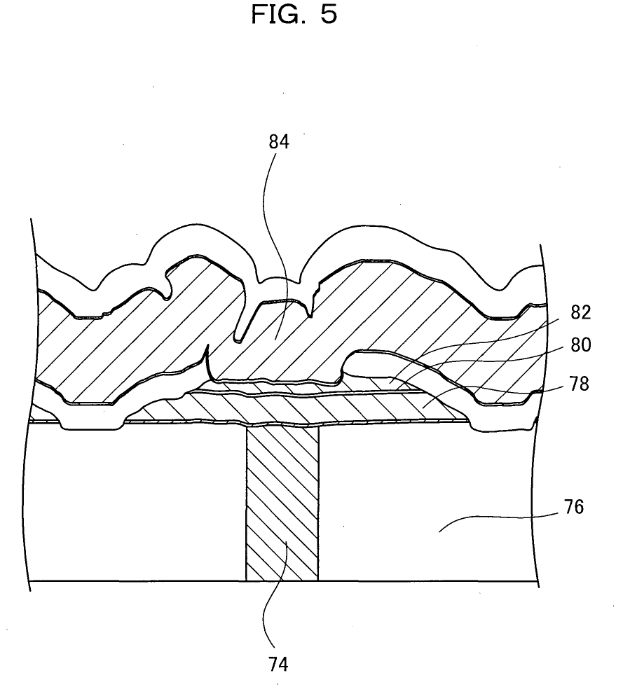

A description will be made of results obtained by evaluating the resistance storage element and the non-volatile semiconductor storage device according to the present embodiment. FIGS. 3A to 3C are graphs illustrating the current versus voltage characteristic of the resistance storage element according to the present embodiment. FIG. 4A is a cross-sectional view illustrating a resistance storage element according to a comparative example using a sputtered NiO film as the resistance storage layer, and FIG. 4B shows graphs illustrating the current versus voltage characteristic of the resistance storage element according to the comparative example. FIG. 5 is an electron micrograph of a cross-sectional structure of the resistance storage element using the sputtered NiO film as the resistance storage layer.

The dotted lines in FIGS. 3A to 3C and 4B represent the current versus voltage characteristic in a forming process. The forming process is carried out to give a resistance storage element a resistance storage characteristic that allows a high-resistance state and a low-resistance state to be changed reversibly. The forming process involves, for example, applying a voltage equivalent to a dielectric breakdown voltage to the resistance storage layer. It is believed that applying the voltage to the resistance storage element to cause soft breakdown in the resistance storage layer allows filament-like current paths to be formed in the resistance storage layer and the current paths develop the resistance storage characteristic. The forming process only needs to be carried out once in an initial stage, but not any more in later stages. The voltage for the forming process is called a forming voltage.

The solid lines in FIGS. 3A to 3C and 4B represent the current versus voltage characteristic when the set and reset actions are repeated three times in the resistance storage element. Gradually increasing the voltage applied to the resistance storage element in the high-resistance state produces a phenomenon in which the resistance storage element transits from the high-resistance state to the low-resistance state at a certain voltage magnitude and the current abruptly increases (set action). The voltage at which the set action occurs is called a set voltage. On the other hand, gradually increasing the voltage applied to the resistance storage element in the low-resistance state to gradually increase the current flowing through the resistance storage element produces a phenomenon in which the resistance storage element transits from the low-resistance state to the high-resistance state at a certain current magnitude and the current decreases (reset action). The current at which the reset action occurs is called a reset current.

FIG. 3A illustrates the current versus voltage characteristic of the resistance storage element according to an experimental example 1 in which the resistance storage layer is the transition metal oxide film 48 formed by the heat treatment under the first heat treatment condition described above. In the experimental example 1, the forming voltage was 1.32 V. The set voltage when the set and reset actions were repeated three times was 1.32 V, 1.30 V, and 0.80 V in the order of occurrence, and the reset current was 0.91 mA, 0.71 mA, and 0.64 mA in the order of occurrence.

FIG. 3B illustrates the current versus voltage characteristic of the resistance storage element according to an experimental example 2 in which the resistance storage layer is the transition metal oxide film 48 formed by the heat treatment under the second heat treatment condition described above. In the experimental example 2, the forming voltage was 0 V. The set voltage when the set and reset actions were repeated three times was 1.04 V, 1.06 V, and 1.08 V in the order of occurrence, and the reset current was 1.01 mA, 0.75 mA, and 0.88 mA in the order of occurrence.

FIG. 3C illustrates the current versus voltage characteristic of the resistance storage element according to an experimental example 3 in which the resistance storage layer is the transition metal oxide film 48 formed by the heat treatment under the third heat treatment condition described above. In the experimental example 3, the forming voltage was 0 V. The set voltage when the set and reset actions were repeated three times was 1.26 V, 1.40 V, and 1.46 V in the order of occurrence, and the reset current was 0.75 mA, 1.05 mA, and 1.15 mA in the order of occurrence.

The set and reset actions occurred in the resistance storage elements according to the experimental examples 2 and 3 that had undergone no forming process. When a resistance storage element in an initial state has a low resistance, no forming occurs in some cases. For example, when the entire Ni is not converted into NiO but part of the Ni is left, the resistance of the entire element decreases and the element functions without undergoing the forming process. When the degree of oxidation of the NiO is low, the resistance of the entire element also decreases and the element functions in some cases without undergoing the forming process.

On the other hand, FIG. 4B illustrates the current versus voltage characteristic of the resistance storage element according to the comparative example in which the resistance storage element includes a lower electrode layer 68 made of Pt, a resistance storage layer 70 formed of a sputtered NiO film and having a film thickness of 20 nm, and an upper electrode layer 72 made of Pt. In the comparative example, the forming voltage was 5 V. The set voltage when the set and reset actions were repeated three times was 1.20 V, 1.40 V, and 1.60 V in the order of occurrence, and the reset current was 10 mA, 20 mA, and 20 mA in the order of occurrence.

As seen from the results described above, the voltage and current levels for the operation in the experimental examples 1 to 3, in particular, the forming voltage and reset current levels are smaller than those in the comparative example. It is seen that the resistance storage element according to the present embodiment can develop the resistance storage characteristic by applying a forming voltage of 3.3 V or lower, even 1.5 V or lower to the transition metal oxide film 48.

The evaluation results described above show that the present embodiment allows a resistance storage element operable at low voltage and current levels to be provided.

When the transition metal oxide film used as the resistance storage layer is formed by sputtering as in the comparative example, and the thus formed transition metal oxide film has a relatively small thickness, a step-shaped disconnected portion may occur in the transition metal oxide film and hence the electrodes may be shorted.

FIG. 5 is an electron micrograph of a cross-sectional structure of a resistance storage element using a sputtered NiO film and having a film thickness of 10 nm as the resistance storage layer. As illustrated in FIG. 5, on an interlayer insulating film 76 in which a tungsten plug 74 is embedded are formed a resistance storage element including a lower electrode layer 78 formed of a Pt film, a resistance storage layer 80 formed of an NiO film having a film thickness of 10 nm, and an upper electrode layer 82 formed of a Pt film. An aluminum wiring line 84 is connected to the upper electrode layer 82.

As seen from FIG. 5, the NiO film 80 forming the resistance storage layer, when having the small film thickness of 10 nm, has corrugated undulations reflecting irregularities of the underlying interlayer insulating film 76 and tungsten plug 74. Therefore, when the NiO film 80 is simply formed by sputtering to have a small thickness, a step-shaped disconnected portion may occur in the NiO film 80 and hence the lower electrode layer 78 and the upper electrode layer 82 may be shorted.

In contrast, in the present embodiment, oxygen contained in the noble metal oxide film 58 in the upper electrode layer 50 is supplied to the transition metal film 46 to oxidize the transition metal film 46 into the transition metal oxide film 48, which becomes the resistance storage layer. In this case, even when the thus formed transition metal oxide film 48 is relatively thin, for example, has a film thickness of 10 nm or smaller, no step-shaped disconnected portion will be produced in the transition metal oxide film 48. No defect due to short circuit will therefore occur, and a resistance storage element operable at low voltage and current levels can be provided.

### Second Embodiment

A description will be made of a resistance storage element, a non-volatile semiconductor storage device using the resistance storage element, and a method for manufacturing the resistance storage element according to a second embodiment of the present invention. The same components as those of the resistance storage element and the non-volatile semiconductor storage device according to the first embodiment have the same reference characters and description thereof will be omitted or simplified.

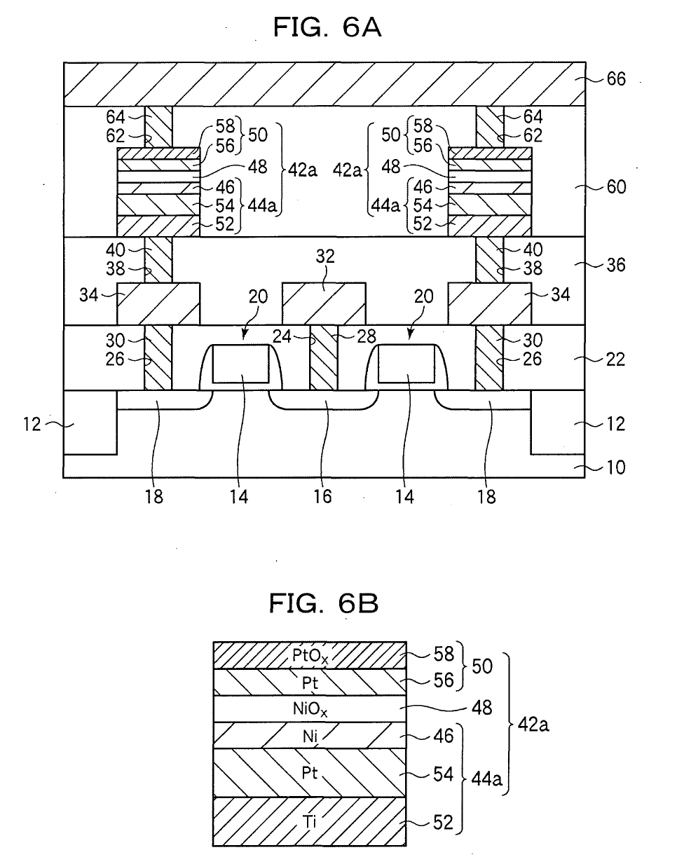

The resistance storage element and the non-volatile semiconductor storage device according to the present embodiment will be described with reference to FIGS. 6A and 6B. FIG. 6A is a cross-sectional view illustrating the non-volatile semiconductor storage device according to the present embodiment. FIG. 6B is an enlarged view of only the resistance storage element.

In the resistance storage element according to the present embodiment, when the transition metal film 46 is oxidized in the method for manufacturing the resistance storage element according to the first embodiment, the entire transition metal film 46 is not oxidized, but part of the transition metal film 46 is left, and the remaining transition metal film 46 is present between the noble metal film 54 and the transition metal oxide film 48.

As illustrated in FIG. 6A, resistance storage elements 42a are formed on the interlayer insulating film 36 in which the contact plugs 40 have been embedded. Each of the resistance storage elements 42a includes a lower electrode layer 44a electrically connected to the corresponding source/drain diffusion layer 18 via the corresponding contact plug 40, relay wiring line 34, and contact plug 30, the resistance storage layer 48 formed on the lower electrode layer 44a, and the upper electrode layer 50 formed on the resistance storage layer 48.

The lower electrode layer 44a is a film obtained by stacking the close contact layer 52, the noble metal film 54, and the transition metal film 46 containing Ni. As will be described later, the transition metal film 46 is what is left when the entire transition metal film 46 is not oxidized in the process in which the transition metal film 46 is oxidized to form the transition metal oxide film 48.

The resistance storage layer 48 has a transition metal oxide film containing NiOₓ. The transition metal oxide film 48 is formed, as will be described later, by forming the noble metal oxide film 58, which forms the upper electrode layer 50, on the transition metal film 46 and carrying out heat treatment to supply oxygen contained in the noble metal oxide film 58 to the transition metal film 46 so as to oxidize part of the transition metal film 46.

The upper electrode layer 50 includes the noble metal oxide film 58 containing PtOₓ and the noble metal film 56 containing Pt, which is the noble metal contained in the noble metal oxide film 58, the noble metal film 56 formed between the noble metal oxide film 58 and the transition metal oxide film 48.

It has been found that the transition metal film 46 formed between the noble metal film 54 and the transition metal oxide film 48 in the present embodiment can further reduce the reset current. Although the detail of the reset current reduction mechanism has not been clearly understood, the thus formed transition metal film 46 seems to prevent diffusion of the element from the noble metal film 54 to the transition metal oxide film 48 and diffusion of oxygen from the transition metal oxide film 48 to the noble metal film 54.

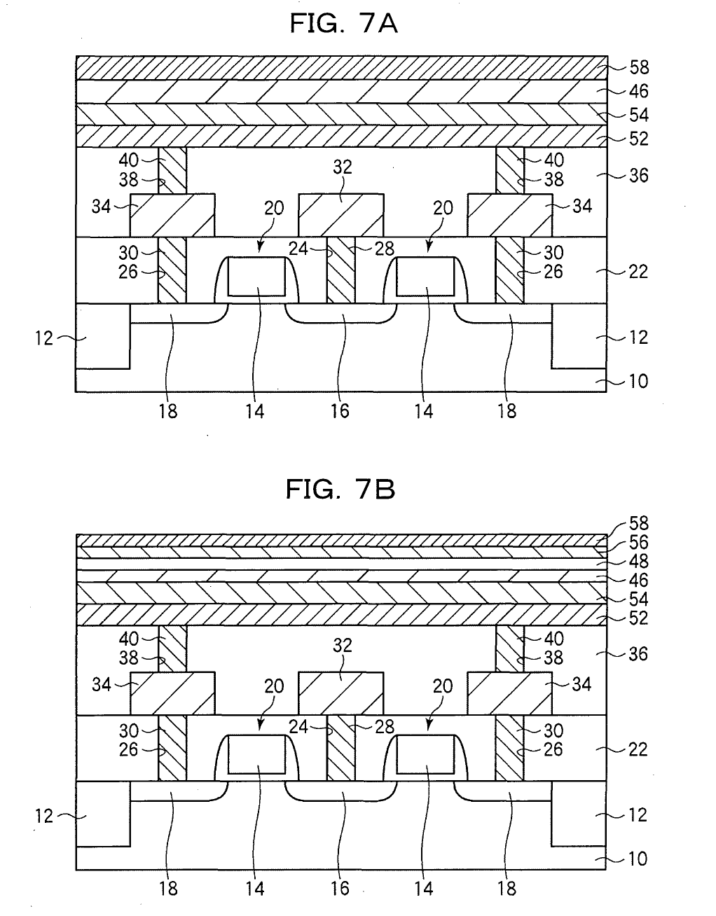

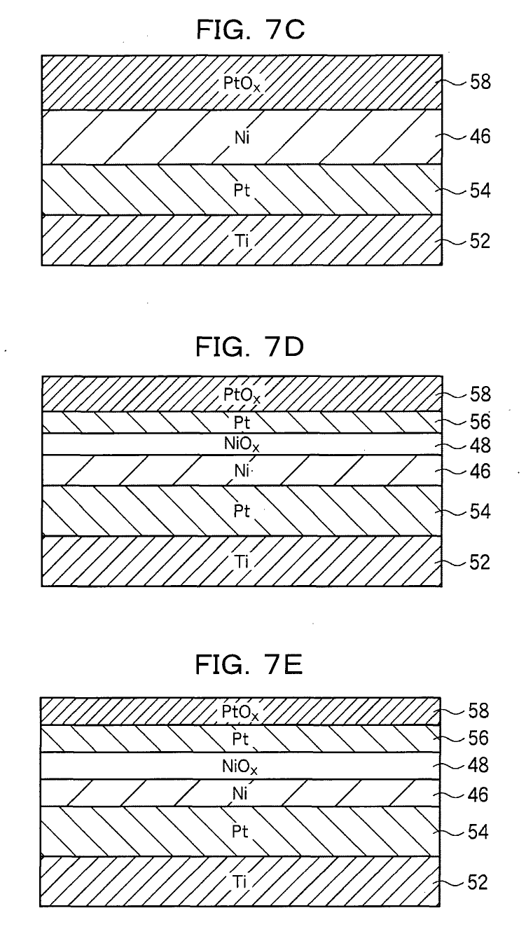

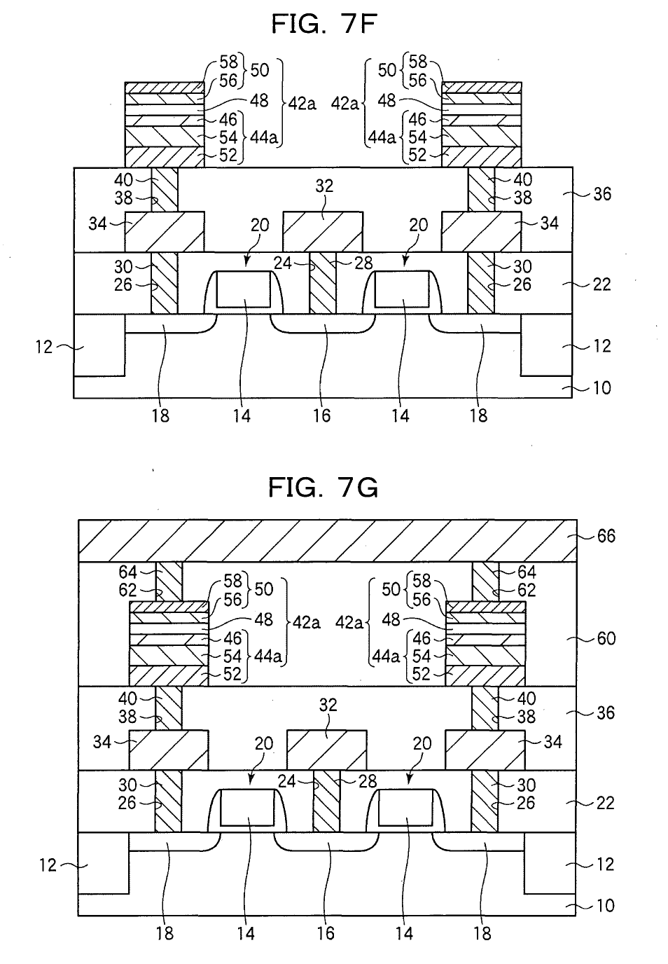

A method for manufacturing the resistance storage element and the non-volatile semiconductor storage device according to the present embodiment will be described below. FIGS. 7A to 7G are process cross-sectional views illustrating the method for manufacturing the resistance storage element and the non-volatile semiconductor storage device according to the present embodiment.

The contact plugs 40 and other components formed before the contact plugs 40 are first formed in the same method for manufacturing the resistance storage element and the non-volatile semiconductor storage device according to the first embodiment illustrated in FIGS. 2A to 2D.

Sputtering or any other suitable method is then used to sequentially form the close contact layer 52 including a Ti film, the noble metal film 54 including a Pt film, the transition metal film 46 including an Ni film, and the noble metal oxide film 58 including a PtOₓ film on the interlayer insulating film 36 in which the contact plugs 40 have been embedded, as in the first embodiment (see FIG. 7A).

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the noble metal oxide film 58 to be supplied to the transition metal film 46 so as to oxidize part of the transition metal film 46. In the present embodiment, the heat treatment condition is adjusted as appropriate, for example, the heat treatment period is shortened as compared to that in the first embodiment, not to oxidize the entire transition metal film 46 but to leave part of the transition metal film 46.

FIGS. 7C to 7E are enlarged views illustrating how part of the transition metal film 46 is oxidized in the present embodiment.

When the heat treatment is carried out after the noble metal oxide film 58 has been formed on the transition metal film 46 as illustrated in FIG. 7C, oxygen contained in the noble metal oxide film 58 dissociates therefrom and is supplied to the transition metal film 46, as illustrated in FIG. 7D. The oxygen supplied from the noble metal oxide film 58 oxidizes the transition metal film 46 gradually from its surface to form the transition metal oxide film 48 in the transition metal film 46. As the noble metal oxide film 58 is reduced, the noble metal film 56 containing the noble metal contained in the noble metal oxide film 58 is formed in the lower portion of the noble metal oxide film 58.

In the present embodiment, adjusting the heat treatment condition as appropriate allows part of the transition metal film 46 to be oxidized to form the transition metal oxide film 48 and the remaining transition metal film 46 to be left under the transition metal oxide film 48, as illustrated in FIG. 7E.

On the interlayer insulating film 36 are thus formed a stacked film including the close contact layer 52, the noble metal film 54, the transition metal film 46, the transition metal oxide film 48, the noble metal film 56, and the noble metal oxide film 58 (see FIG. 7B).

Photolithography and dry etching are then used to pattern the noble metal oxide film 58, the noble metal film 56, the transition metal oxide film 48, the transition metal film 46, the noble metal film 54, and the close contact layer 52 to form the resistance storage elements 42a, each of which having the lower electrode layer 44a including a stacked film comprised of the close contact layer 52, the noble metal film 54, and the transition metal film 46, the resistance storage layer 48 including the transition metal oxide film, and the upper electrode layer 50 including the noble metal film 56 and the noble metal oxide film 58 (see FIG. 7F).

The contact plugs 64, the bit line 66, and other components are then formed in the same method for manufacturing the resistance storage element and the non-volatile semiconductor storage device according to the first embodiment illustrated in FIGS. 2K and 2L. The non-volatile semiconductor storage device is thus completed (see FIG. 7G).

As described in the present embodiment, part of the transition metal film 46 may be oxidized to form the transition metal oxide film 48, and the remaining transition metal film 46 may be left between the noble metal film 54 and the transition metal oxide film 48. Leaving part of the transition metal film 46 can further reduce the reset current in the resistance storage element.

### Third Embodiment

A description will be made of a resistance storage element, a non-volatile semiconductor storage device using the resistance storage element, and a method for manufacturing the resistance storage element according to a third embodiment of the present invention. The same components as those of the resistance storage elements and the non-volatile semiconductor storage devices according to the first and second embodiments have the same reference characters and description thereof will be omitted or simplified.

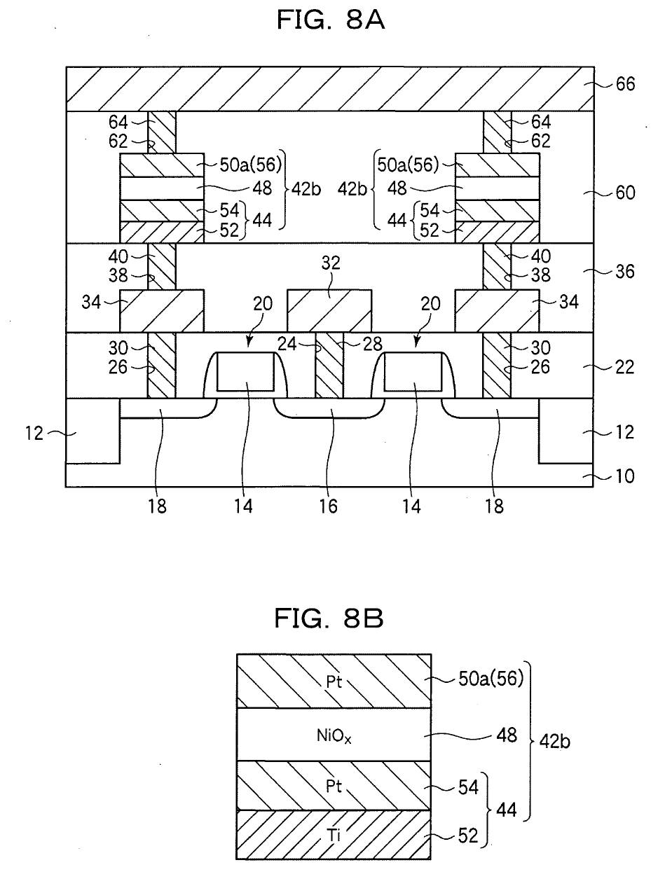

The resistance storage element and the non-volatile semiconductor storage device according to the present embodiment will be first described with reference to FIGS. 8A and 8B. FIG. 8A is a cross-sectional view illustrating the non-volatile semiconductor storage device according to the present embodiment. FIG. 8B is an enlarged view of only the resistance storage element.

In the resistance storage element according to the present embodiment, when the transition metal film 46 is oxidized in the method for manufacturing the resistance storage element according to the first embodiment, the entire oxygen contained in the noble metal oxide film 58 is allowed to dissociate to convert the noble metal oxide film 58 into the noble metal film 56. The resistance storage element therefore has an upper electrode layer 50a including the noble metal film 56.

As illustrated in FIG. 8A, resistance storage elements 42b are formed on the interlayer insulating film 36 in which the contact plugs 40 have been embedded. Each of the resistance storage elements 42b includes the lower electrode layer 44 electrically connected to the corresponding source/drain diffusion layer 18 via the corresponding contact plugs 40, relay wiring line 34, and the contact plug 30, the resistance storage layer 48 formed on the lower electrode layer 44, and the upper electrode layer 50a formed on the resistance storage layer 48.

The lower electrode layer 44 has a stacked film comprised of the close contact layer 52 and the noble metal film 54.

The resistance storage layer 48 has a transition metal oxide film containing NiOₓ. The transition metal oxide film 48 is formed, as will be described later, by forming the noble metal oxide film 58 on the transition metal film 46 and carrying out heat treatment to supply oxygen contained in the noble metal oxide film 58 to the transition metal film 46 so as to oxidize the transition metal film 46.

The upper electrode layer 50a has the noble metal film 56 containing Pt. The noble metal film 56 is formed from the noble metal oxide film 58, as will be described later, by causing all of the oxygen contained in the noble metal oxide film 58 containing PtOₓ to dissociate therefrom when the transition metal oxide film 48 is formed.

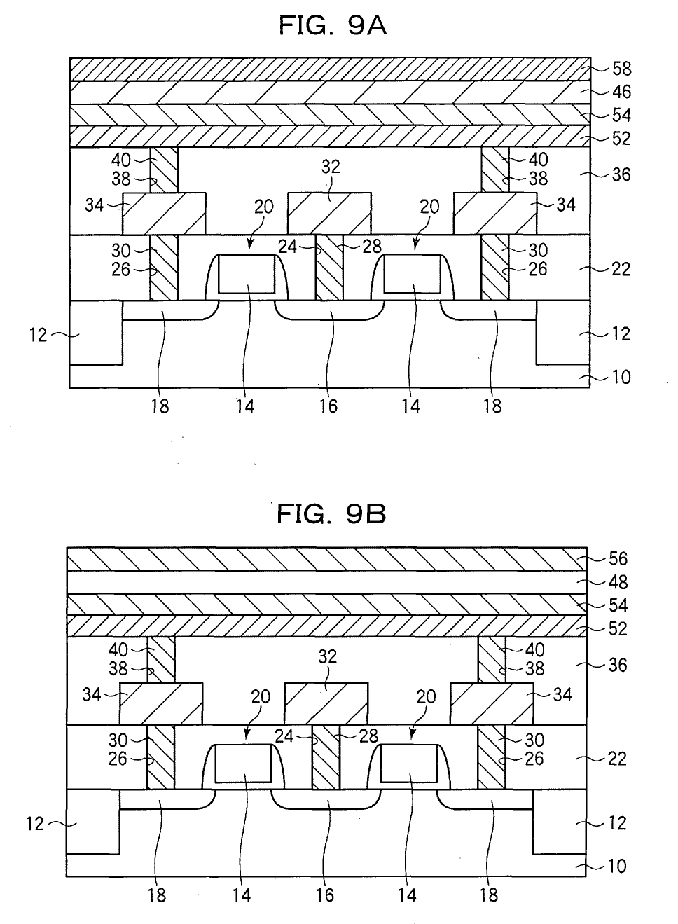

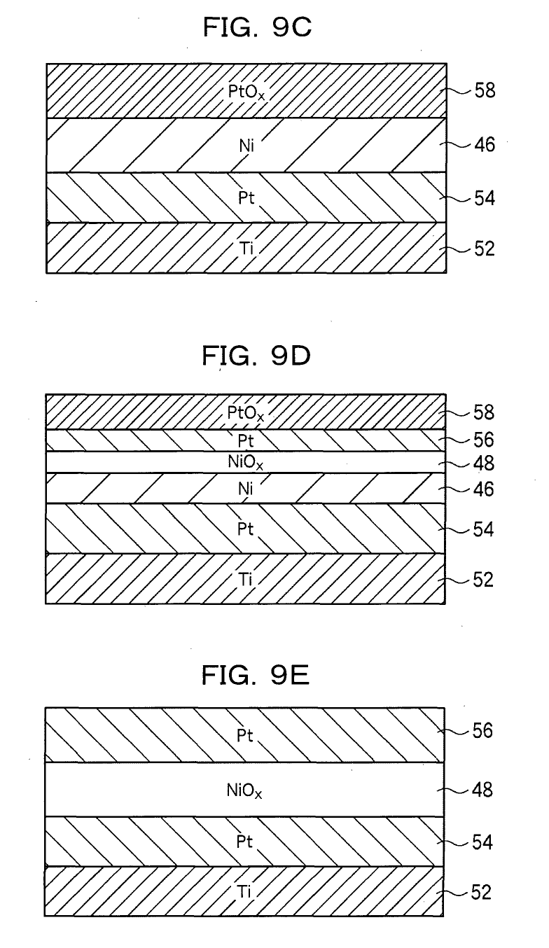

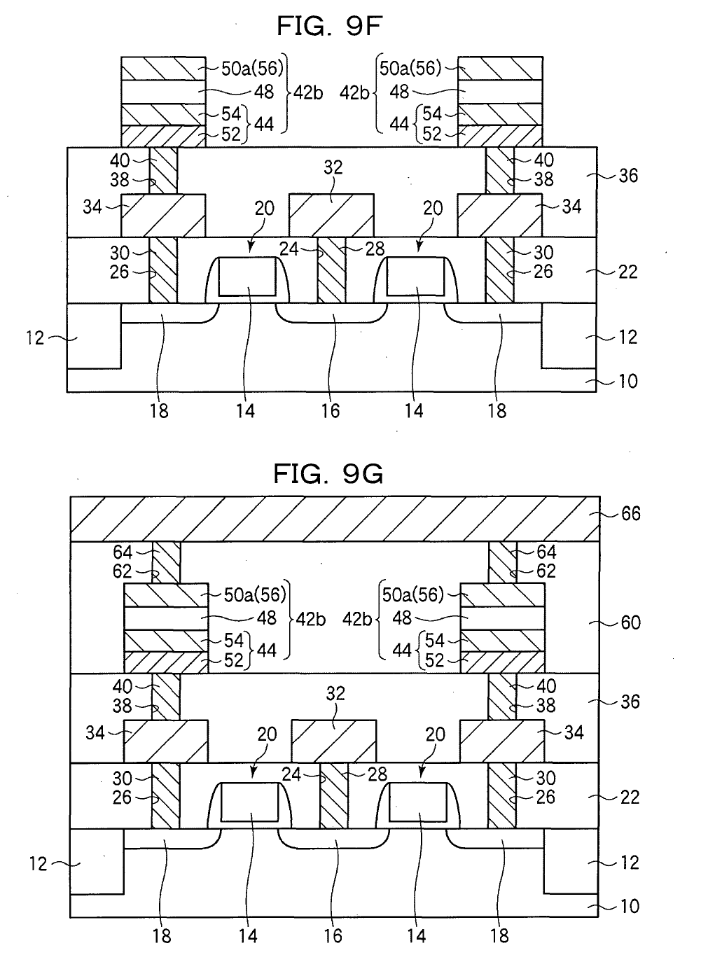

A method for manufacturing the resistance storage element and the non-volatile semiconductor storage device according to the present embodiment will be described with reference to FIGS. 9A to 9G. FIGS. 9A to 9G are process cross-sectional views illustrating the method for manufacturing the resistance storage element and the non-volatile semiconductor storage device according to the present embodiment.

The contact plugs 40 and other components formed before the contact plugs 40 are first formed in the same method for manufacturing the resistance storage element and the non-volatile semiconductor storage device according to the first embodiment illustrated in FIGS. 2A to 2D.

Sputtering or any other suitable method is then used to sequentially form the close contact layer 52 including a Ti film, the noble metal film 54 including a Pt film, the transition metal film 46 including an Ni film, and the noble metal oxide film 58 including a PtOₓ film on the interlayer insulating film 36 in which the contact plugs 40 have been embedded, as in the first embodiment (see FIG. 9A).

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the noble metal oxide film 58 to be supplied to the transition metal film 46 so as to oxidize the transition metal film 46. In the present embodiment, the heat treatment condition is adjusted as appropriate to cause the entire oxygen contained in the noble metal oxide film 58 to dissociate therefrom.

FIGS. 9C to 9E are enlarged views illustrating how the transition metal film 46 is oxidized in the present embodiment.

When the heat treatment is carried out after the noble metal oxide film 58 has been formed on the transition metal film 46 as illustrated in FIG. 9C, oxygen contained in the noble metal oxide film 58 dissociates therefrom and is supplied to the transition metal film 46, as illustrated in FIG. 9D. The oxygen supplied from the noble metal oxide film 58 oxidizes the transition metal film 46 gradually from its surface to form the transition metal oxide film 48 in the transition metal film 46. As the noble metal oxide film 58 is reduced, the noble metal film 56 made of the noble metal that forms the noble metal oxide film 58 is formed in the lower portion of the noble metal oxide film 58.

In the present embodiment, adjusting the heat treatment condition as appropriate allows the entire oxygen contained in the noble metal oxide film 58 to dissociate therefrom. The transition metal film 46 is thus oxidized into the transition metal oxide film 48, and the noble metal oxide film 58 is reduced into the noble metal film 56, as illustrated in FIG. 9E.

On the interlayer insulating film 36 are thus formed a stacked film including the close contact layer 52, the noble metal film 54, the transition metal oxide film 48, and the noble metal film 56 (see FIG. 9B).

Photolithography and dry etching are then used to pattern the noble metal film 56, the transition metal oxide film 48, the noble metal film 54, and the close contact layer 52 to form the resistance storage elements 42b, each of which having the lower electrode layer 44 including the stacked film comprised of the close contact layer 52 and the noble metal film 54, the resistance storage layer 48 including the transition metal oxide film, and the upper electrode layer 50a including the noble metal film 56 (see FIG. 9F).

The contact plugs 64, the bit line 66, and other components are then formed in the same method for manufacturing the resistance storage element and the non-volatile semiconductor storage device according to the first embodiment illustrated in FIGS. 2K and 2L. The non-volatile semiconductor storage device is thus completed (see FIG. 9G).

As described in the present embodiment, when the transition metal film 46 is oxidized into the transition metal oxide film 48, the entire oxygen contained in the noble metal oxide film 58 may be dissociated therefrom to convert the noble metal oxide film 58 into the noble metal film 56, which then forms the upper electrode layer 50a.

### Fourth Embodiment

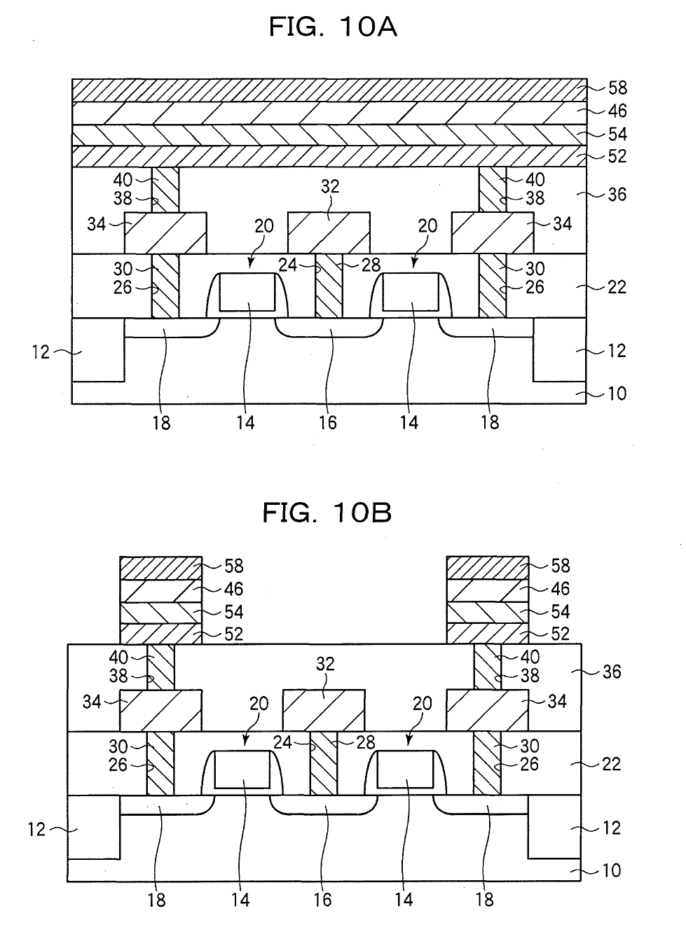

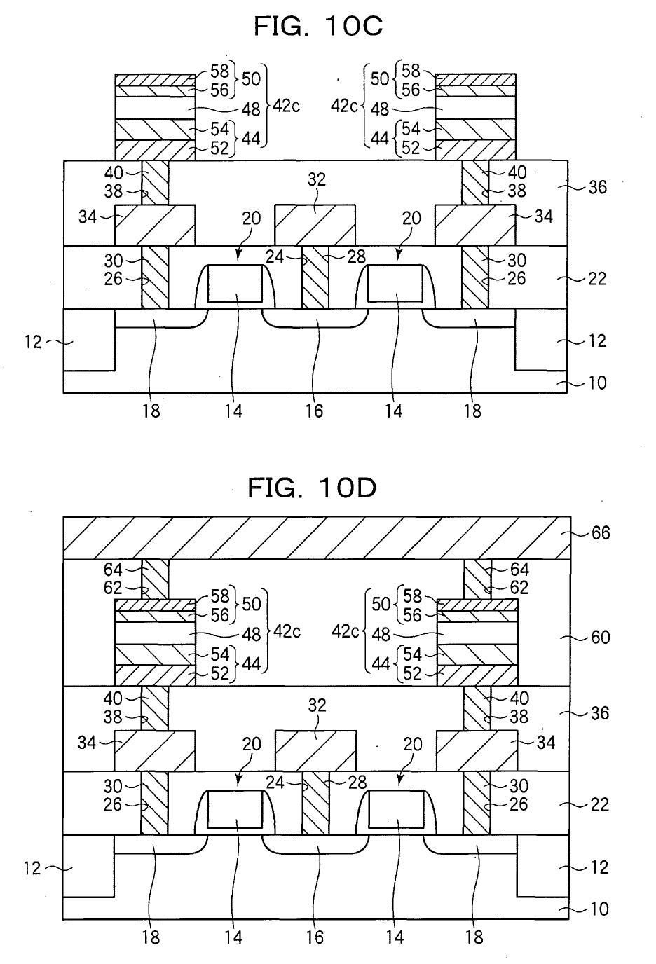

A method for manufacturing a resistance storage element and a non-volatile semiconductor storage device according to a fourth embodiment of the present invention will be described with reference to FIGS. 10A to 10D. FIGS. 10A to 10D are process cross-sectional views illustrating the method for manufacturing the resistance storage element and the non-volatile semiconductor storage device according to the present embodiment. The same components as those of the resistance storage elements and the non-volatile semiconductor storage devices according to the first to third embodiments have the same reference characters and description thereof will be omitted or simplified.

The method for manufacturing the resistance storage element and the non-volatile semiconductor storage device according to the present embodiment involves forming a stacked film comprised of the close contact layer 52, the noble metal film 54, the transition metal film 46, and the noble metal oxide film 58, patterning the stacked film into the shape of the resistance storage element, and carrying out heat treatment for forming the transition metal oxide film 48.

The contact plugs 40 and other components formed before the contact plugs 40 are formed in the same method for manufacturing the resistance storage element and the non-volatile semiconductor storage device according to the first embodiment illustrated in FIGS. 2A to 2D.

Sputtering or any other suitable method is then used to sequentially form the close contact layer 52 including a Ti film, the noble metal film 54 including a Pt film, the transition metal film 46 including an Ni film, and the noble metal oxide film 58 including a PtOₓ film on the interlayer insulating film 36 in which the contact plugs 40 have been embedded, as in the first embodiment (see FIG. 10A).

Photolithography and dry etching are then used to pattern the stacked film including the noble metal oxide film 58, the transition metal film 46, the noble metal film 54, and the close contact layer 52 into the shape of the resistance storage element (see FIG. 10B).

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the noble metal oxide film 58 to be supplied to the transition metal film 46 so as to oxidize the transition metal film 46 into the transition metal oxide film 48. As the noble metal oxide film 58 is reduced, the noble metal film 56 containing the noble metal that forms the noble metal oxide film 58 is formed in the lower portion of the noble metal oxide film 58.

In the present embodiment, the heat treatment is thus carried out after the stacked film has been patterned into the shape of the resistance storage element. Therefore, when the heat treatment atmosphere contains an oxidizing gas, the close contact layer 52 is oxidized, which may degrade the electric connection between the lower electrode layer 44 and the contact plug 40. Therefore, when the heat treatment is carried out in an atmosphere containing an oxidizing gas, it is desirable to adjust the heat treatment condition as appropriate, for example, by setting the concentration of the oxidizing gas to a low level.

Resistance storage elements 42c are thus formed, each of the resistance storage elements 42c including the lower electrode layer 44 including a stacked film comprised of the close contact layer 52 and the noble metal film 54, the resistance storage layer 48 including the transition metal oxide film, and the upper electrode layer 50 including the noble metal film 56 and the noble metal oxide film 58 (see FIG. 10C).

The contact plugs 64, the bit line 66, and other components are then formed in the same method for manufacturing the resistance storage element and the non-volatile semiconductor storage device according to the first embodiment illustrated in FIGS. 2K and 2L. The non-volatile semiconductor storage device is thus completed (see FIG. 10D).

As described in the present embodiment, the heat treatment for forming the transition metal oxide film 48 may be carried out after the stacked film including the close contact layer 52, the noble metal film 54, the transition metal film 46, and the noble metal oxide film 58 is formed and the stacked film is patterned into the shape of the resistance storage element.

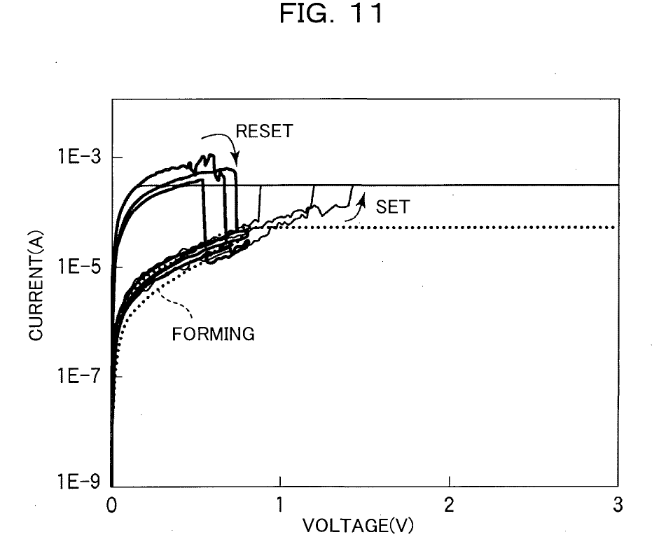

A description will be made of results obtained by evaluating the resistance storage element and the non-volatile semiconductor storage device according to the present embodiment. FIG. 11 illustrates graphs illustrating the current versus voltage characteristic of the resistance storage element according to the present embodiment. The dotted line in FIG. 11 represents the current versus voltage characteristic in the forming process. The solid lines in FIG. 11 represent the current versus voltage characteristic when the set and reset actions are repeated three times in the resistance storage element.

FIG. 11 illustrates the current versus voltage characteristic of the resistance storage element according to an experimental example 4 in which the resistance storage layer is the transition metal oxide film 48 formed by carrying out heat treatment after the stacked film has been patterned into the shape of the resistance storage element as described above. In the experimental example 4, the forming voltage was 1.20 V. The set voltage when the set and reset actions were repeated three times was 0.88 V, 1.20 V, and 1.42 V in the order of occurrence, and the reset current was 1.01 mA, 0.37 mA, and 0.57 mA in the order of occurrence.

As seen from FIGS. 11 and 4B, in the experimental example 4 as well, the voltage and current levels for the operation, in particular, the forming voltage and reset current levels are smaller than those in the comparative example.

The evaluation results described above illustrate that the present embodiment allows a resistance storage element operable at low voltage and current levels to be provided.

### Fifth Embodiment

A description will be made of a resistance storage element, a non-volatile semiconductor storage device using the resistance storage element, and a method for manufacturing the resistance storage element according to a fifth embodiment of the present invention. The same components as those of the resistance storage elements and the non-volatile semiconductor storage devices according to the first to fourth embodiments have the same reference characters and description thereof will be omitted or simplified.

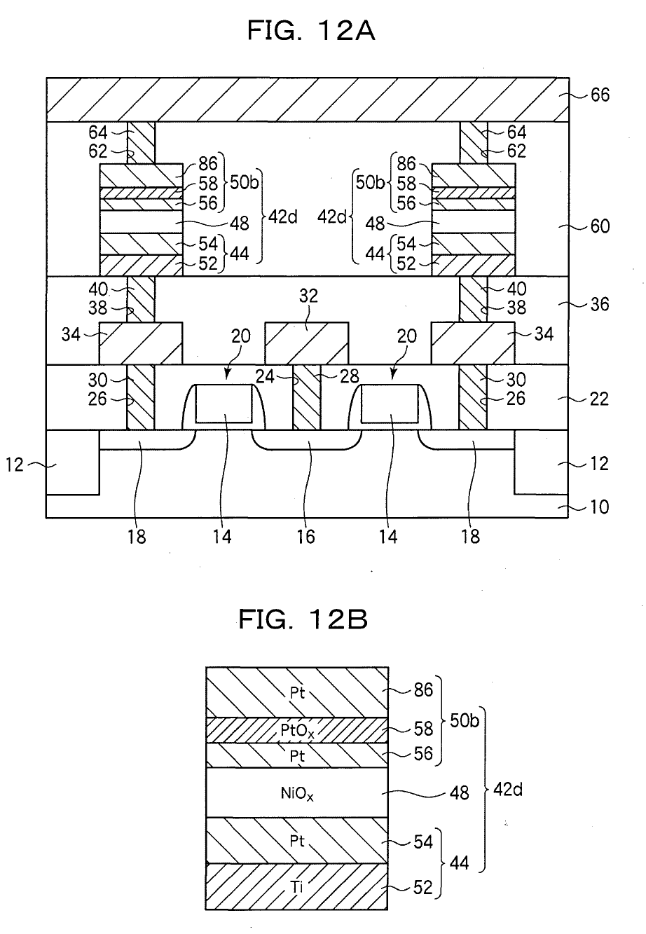

The resistance storage element and the non-volatile semiconductor storage device according to the present embodiment will be first described with reference to FIGS. 12A and 12B. FIG. 12A is a cross-sectional view illustrating the non-volatile semiconductor storage device according to the present embodiment. FIG. 12B is an enlarged view of only the resistance storage element.

The resistance storage element according to the present embodiment is based on the resistance storage element according to the first embodiment but differs therefrom in that a noble metal film 86 is formed on the noble metal oxide film 58 to prevent upward diffusion of oxygen from the noble metal oxide film 58 and the resistance storage element has an upper electrode layer 50b including the noble metal film 56, the noble metal oxide film 58, and the noble metal film 86.

As illustrated in FIG. 12A, resistance storage elements 42d are formed on the interlayer insulating film 36 in which the contact plugs 40 have been embedded. Each of the resistance storage elements 42d includes the lower electrode layer 44 electrically connected to the corresponding source/drain diffusion layer 18 via the corresponding contact plug 40, relay wiring line 34, and contact plug 30, the resistance storage layer 48 formed on the lower electrode layer 44, and the upper electrode layer 50b formed on the resistance storage layer 48.

The lower electrode layer 44 has a stacked film comprised of the close contact layer 52 and the noble metal film 54.

The resistance storage layer 48 has a transition metal oxide film containing NiOₓ. The transition metal oxide film 48 is formed, as will be described later, by forming the noble metal oxide film 58 on the transition metal film 46 and carrying out heat treatment to supply oxygen contained in the noble metal oxide film 58 to the transition metal film 46 so as to oxidize the transition metal film 46.

The upper electrode layer 50b includes the noble metal oxide film 58 containing PtOₓ; the noble metal film 56 formed between the noble metal oxide film 58 and the transition metal oxide film 48, the noble metal film 56 containing Pt, which is a noble metal; and the noble metal film 86 formed on the noble metal oxide film 58, the noble metal film 86 made of Pt.

The noble metal film 86, as will be described later, functions as a diffusion prevention layer that prevents upward diffusion of oxygen from the noble metal oxide film 58 when oxygen contained in the noble metal oxide film 58 is supplied to the transition metal film 46 to oxidize the transition metal film 46. The noble metal film 86 may be made of iridium (Ir) or ruthenium (Ru) instead of Pt. Instead of the noble metal film 86, the diffusion prevention layer can be made of a material less oxidizable than the material of the transition metal film 46. That is, when the transition metal film 46 is made of Ni, the diffusion prevention layer can be made of a material less oxidizable than Ni, such as TiN. The reason why a material less oxidizable than the material of the transition metal film 46 is used as the material of the diffusion prevention layer is because a material more oxidizable than Ni, such as aluminum (Al) and Ti, is disadvantageously oxidized before the transition metal film 46 containing Ni is oxidized when the transition metal film 46 containing Ni is oxidized.

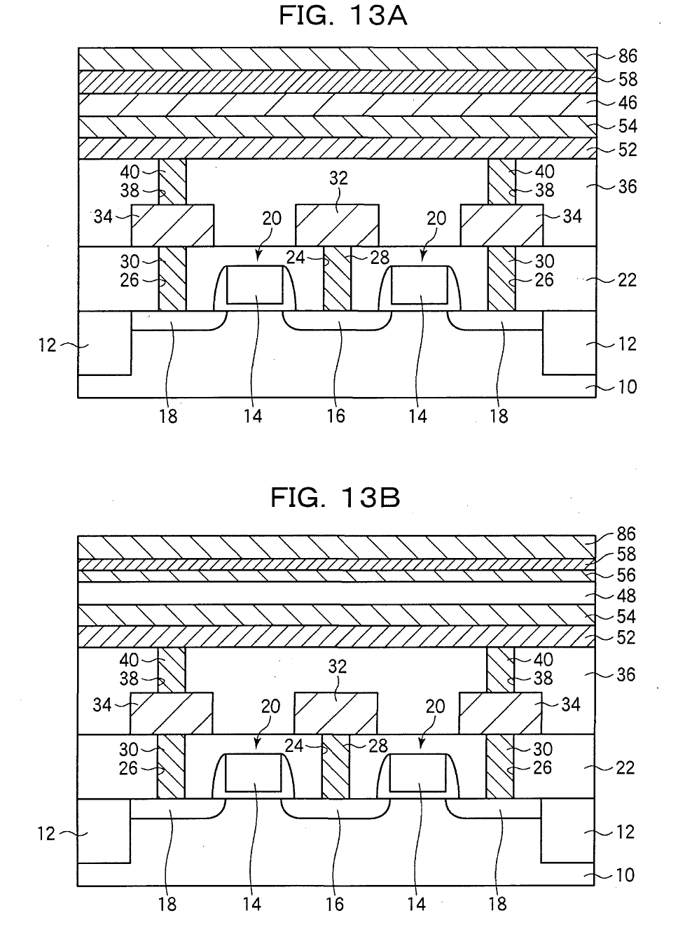

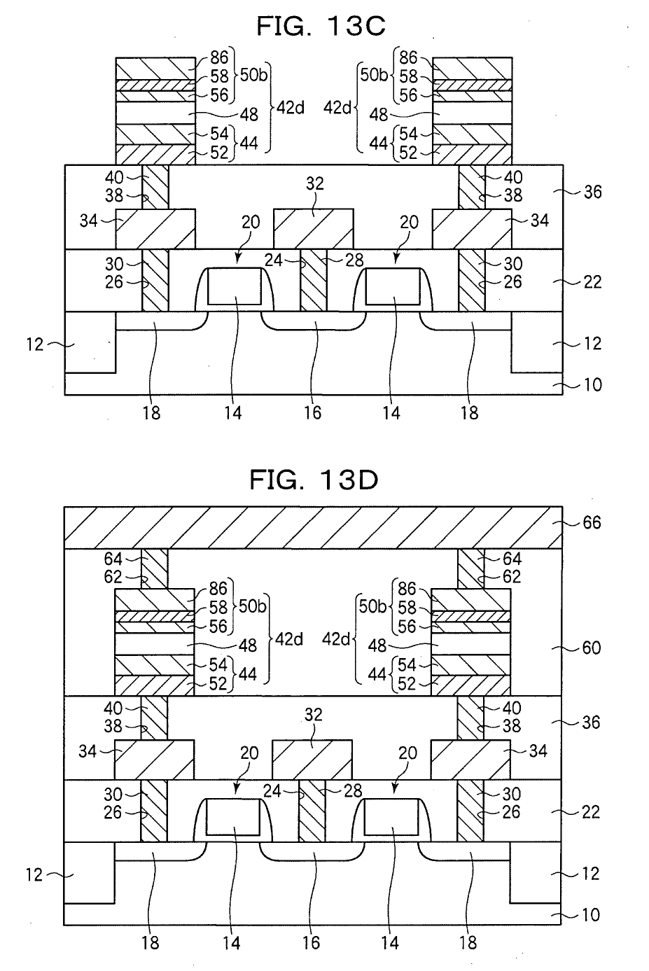

A method for manufacturing the resistance storage element and the non-volatile semiconductor storage device according to the present embodiment will be described with reference to FIGS. 13A to 13D. FIGS. 13A to 13D are process cross-sectional views illustrating the method for manufacturing the resistance storage element and the non-volatile semiconductor storage device according to the present embodiment.

The contact plugs 40 and other components formed before the contact plugs 40 are first formed in the same method for manufacturing the resistance storage element and the non-volatile semiconductor storage device according to the first embodiment illustrated in FIGS. 2A to 2D.

Sputtering or any other suitable method is then used to sequentially form the close contact layer 52 including a Ti film, the noble metal film 54 including a Pt film, the transition metal film 46 including an Ni film, and the noble metal oxide film 58 including a PtOₓ film on the interlayer insulating film 36 in which the contact plugs 40 have been embedded, as in the first embodiment.

Sputtering or any other suitable method is then used to deposit a Pt film on the noble metal oxide film 58 to form the noble metal film 86 including a Pt film (see FIG. 13A).

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the noble metal oxide film 58 to be supplied to the transition metal film 46 so as to oxidize the transition metal film 46 into the transition metal oxide film 48. As the noble metal oxide film 58 is reduced, the noble metal film 56 made of the noble metal that forms the noble metal oxide film 58 is formed in the lower portion of the noble metal oxide film 58.

In the present embodiment, the noble metal film 86 is formed on the noble metal oxide film 58, the noble metal film 86 functioning as the diffusion prevention layer that prevents upward diffusion of oxygen from the noble metal oxide film 58. The present embodiment thus allows oxygen contained in the noble metal oxide film 58 to be efficiently supplied to the transition metal film 46, whereby the period for the heat treatment for oxidizing the transition metal film 46 can be shortened.

On the interlayer insulating film 36 are thus formed a stacked film comprised of the close contact layer 52, the noble metal film 54, the transition metal oxide film 48, the noble metal film 56, the noble metal oxide film 58, and the noble metal film 86 (see FIG. 13B).

Photolithography and dry etching are then used to pattern the noble metal film 86, the noble metal oxide film 58, the noble metal film 56, the transition metal oxide film 48, the noble metal film 54, and the close contact layer 52 to form the resistance storage elements 42d, each of which having the lower electrode layer 44 including the stacked film comprised of the close contact layer 52 and the noble metal film 54, the resistance storage layer 48 including the transition metal oxide film, and the upper electrode layer 50b including the noble metal film 56, the noble metal oxide film 58, and the noble metal film 86 (see FIG. 13C).

The contact plugs 64, the bit line 66, and other components are formed in the same method for manufacturing the resistance storage element and the non-volatile semiconductor storage device according to the first embodiment illustrated in FIGS. 2K and 2L. The non-volatile semiconductor storage device is thus completed (see FIG. 13D).

As described in the present embodiment, the noble metal film 86 that functions as the diffusion prevention layer for preventing upward diffusion of oxygen from the noble metal oxide film 58 may be formed on the noble metal oxide film 58. Forming the noble metal film 86 allows oxygen contained in the noble metal oxide film 58 to be efficiently supplied to the transition metal film 46, whereby the period for the heat treatment for oxidizing the transition metal film 46 can be shortened.

### Sixth Embodiment

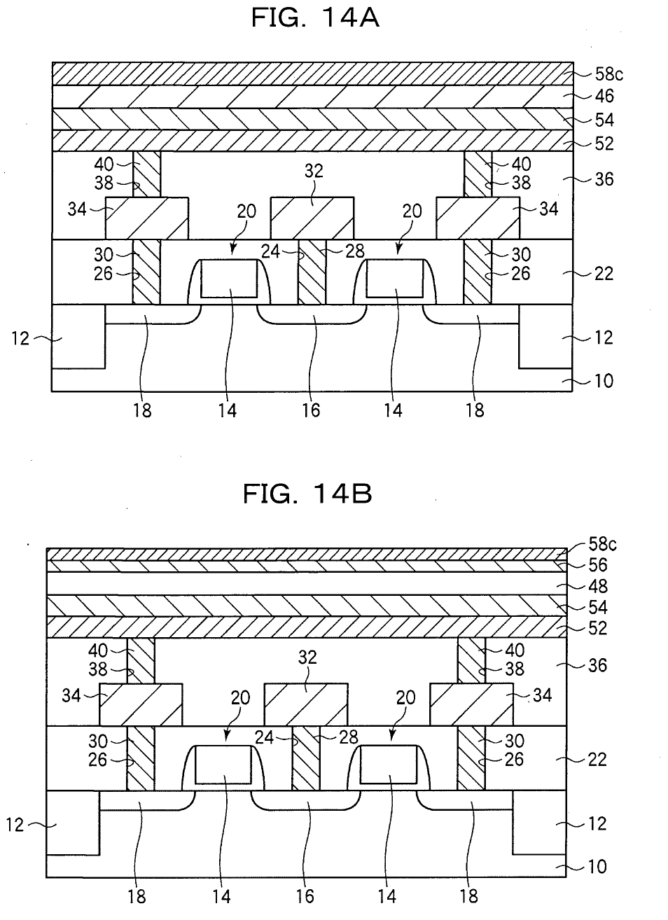

A method for manufacturing a resistance storage element and a non-volatile semiconductor storage device according to a sixth embodiment of the present invention will be described with reference to FIGS. 14A and 14B. FIGS. 14A and 14B are process cross-sectional views illustrating the method for manufacturing the resistance storage element and the non-volatile semiconductor storage device according to the present embodiment. The same components as those of the resistance storage elements and the non-volatile semiconductor storage devices according to the first to fifth embodiments have the same reference characters and description thereof will be omitted or simplified.

The method for manufacturing the resistance storage element and the non-volatile semiconductor storage device according to the present embodiment is based on the method for manufacturing the resistance storage element and the non-volatile semiconductor storage device according to the first embodiment but involves forming the noble metal oxide film 58 on the transition metal film 46 while heating the entire structure to form a crystallized noble metal oxide film 58c.

The contact plugs 40 and other components formed before the contact plugs 40 are formed in the same method for manufacturing the resistance storage element and the non-volatile semiconductor storage device according to the first embodiment illustrated in FIGS. 2A to 2D.

Sputtering or any other suitable method is then used to sequentially form the close contact layer 52 including a Ti film, the noble metal film 54 including a Pt film, and the transition metal film 46 including an Ni film on the interlayer insulating film 36 in which the contact plugs 40 have been embedded, as in the first embodiment.

Sputtering or any other suitable method is then used to deposit a PtOₓ film on the transition metal film 46 while the entire structure is heated, for example, at a temperature of 350° C. or lower to form a noble metal oxide film 58c including a PtOₓ film (see FIG. 14A). The noble metal oxide film 58c is crystallized due to the heat during the formation.

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the crystallized noble metal oxide film 58c to be supplied to the transition metal film 46 so as to oxidize the transition metal film 46 into the transition metal oxide film 48. As the noble metal oxide film 58c is reduced, the noble metal film 56 made of the noble metal that forms the noble metal oxide film 58c is formed in the lower portion of the noble metal oxide film 58c.

In the present embodiment, the crystallized noble metal oxide film 58c is formed on the transition metal film 46. The oxygen that has dissociated from the crystallized noble metal oxide film 58c is more activated than the oxygen that has dissociated from the amorphous noble metal oxide film 58. The present embodiment therefore allows the transition metal film 46 to be more efficiently oxidized, whereby the period for the heat treatment for oxidizing the transition metal film 46 can be shortened.

On the interlayer insulating film 36 are thus formed a stacked film including the close contact layer 52, the noble metal film 54, the transition metal oxide film 48, the noble metal film 56, and the noble metal oxide film 58c (see FIG. 14B).

The following processes are the same as those in the method for manufacturing the resistance storage element and the non-volatile semiconductor storage device according to the first embodiment illustrated in FIGS. 2J to 2L, and the description of those processes will be omitted.

As described in the present embodiment, the crystallized noble metal oxide film 58c may be formed on the transition metal film 46. Forming the crystallized noble metal oxide film 58c allows the transition metal film 46 to be more efficiently oxidized, whereby the period for the heat treatment for oxidizing the transition metal film 46 can be shortened.

### Seventh Embodiment

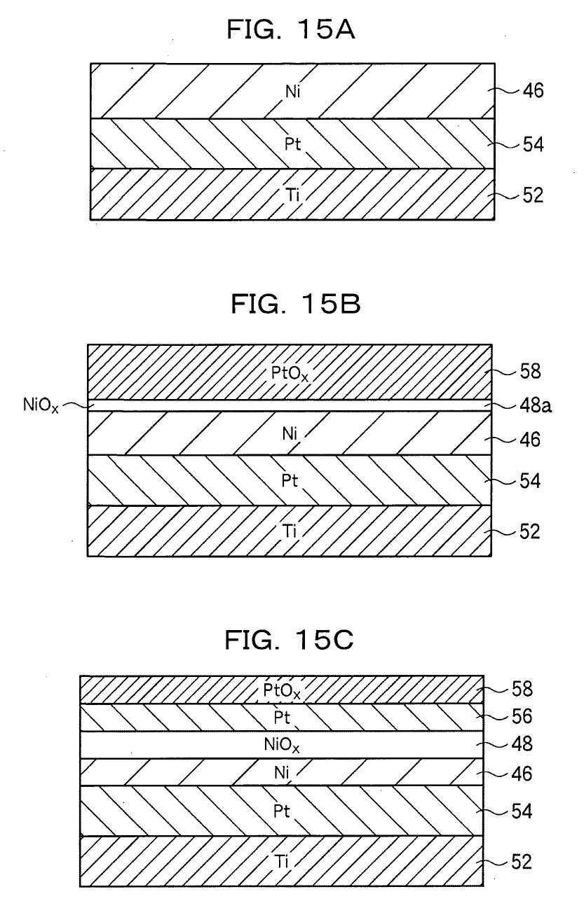

A method for manufacturing a resistance storage element and a non-volatile semiconductor storage device according to a seventh embodiment of the present invention will be described with reference to FIGS. 15A to 15C. FIGS. 15A to 15C are process cross-sectional views illustrating the method for manufacturing the resistance storage element and the non-volatile semiconductor storage device according to the present embodiment. The same components as those of the resistance storage elements and the non-volatile semiconductor storage devices according to the first to sixth embodiments have the same reference characters and description thereof will be omitted or simplified.

While in the above embodiments, the description has been made of the case where oxygen contained in the noble metal oxide film 58 is supplied to the transition metal film 46 to oxidize the transition metal film 46, the surface of the transition metal film 46 may be oxidized before the above oxidation process. In the method for manufacturing the resistance storage element and the non-volatile semiconductor storage device according to the present embodiment, when the noble metal oxide film 58 is formed on the transition metal film 46, the noble metal oxide film 58 is formed while heated in an atmosphere containing oxygen or any other suitable oxidizing gas so as to oxidize the surface of the transition metal film 46 and form a thin transition metal oxide film 48a on the surface of the transition metal film 46.

As illustrated in FIG. 15A, sputtering or any other suitable method is used to sequentially form the close contact layer 52 including a Ti film, the noble metal film 54 including a Pt film, and the transition metal film 46 including an Ni film, as in the first embodiment.

As illustrated in FIG. 15B, sputtering or any other suitable method is then used to deposit a PtOₓ film on the transition metal film 46 while heating the entire structure, for example, at a temperature of 350° C. or lower in an atmosphere containing oxygen or any other suitable oxidizing gas so as to form the noble metal oxide film 58 including the PtOₓ film. In this process, the surface of the transition metal film 46 is oxidized, and a thin transition metal oxide film 48a is formed on the surface of the transition metal film 46.

Heat treatment is then carried out at a temperature within a range from 200 to 750° C., more preferably from 300 to 500° C., for example, in an inert gas atmosphere or a mixed gas atmosphere containing an inert gas and an oxidizing gas. The heat treatment causes oxygen contained in the noble metal oxide film 58 to be supplied to the transition metal film 46 so as to further oxidize the transition metal film 46 into the transition metal oxide film 48, which becomes the resistance storage layer, as illustrated in FIG. 15C. As the noble metal oxide film 58 is reduced, the noble metal film 56 containing the noble metal contained in the noble metal oxide film 58 is formed in the lower portion of the noble metal oxide film 58.

As described in the present embodiment, when the noble metal oxide film 58 is formed on the transition metal film 46, the noble metal oxide film 58 may be formed while heated in an atmosphere containing an oxidizing gas so as to oxidize the surface of the transition metal film 46 and form the thin transition metal oxide film 48a on the surface of the transition metal film 46.

### Eighth Embodiment

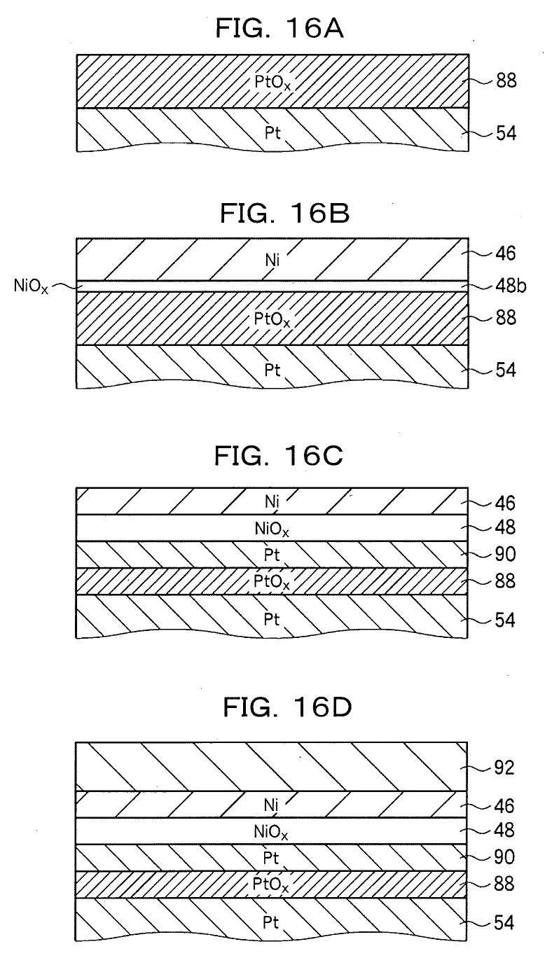

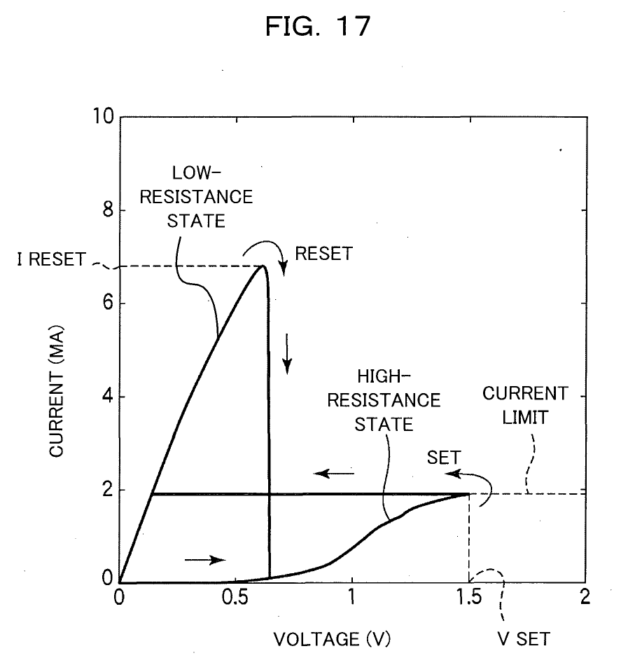

A method for manufacturing a resistance storage element and a non-volatile semiconductor storage device according to an eighth embodiment of the present invention will be described with reference to FIGS. 16A to 16D. FIGS. 16A to 16D are process cross-sectional views illustrating the method for manufacturing the resistance storage element and the non-volatile semiconductor storage device according to the present embodiment. The same components as those of the resistance storage elements and the non-volatile semiconductor storage devices according to the first to seventh embodiments have the same reference characters and description thereof will be omitted or simplified.

While in the above embodiments, the description has been made of the case where the noble metal oxide film 58 is formed on the transition metal film 46 and oxygen contained in the noble metal oxide film 58 is supplied to the transition metal film 46 to oxidize the transition metal film 46, oxygen contained in another noble metal oxide film may be supplied to the transition metal film 46 to oxidize the transition metal film 46. The method for manufacturing the resistance storage element and the non-volatile semiconductor storage device according to the present embodiment involves forming the transition metal film 46 on a noble metal oxide film 88, carrying out heat treatment to supply oxygen contained in the noble metal oxide film 88 to the transition metal film 46 so as to oxidize the transition metal film 46 into the transition metal oxide film 48, which becomes the resistance storage layer.

Sputtering or any other suitable method is used to sequentially form the close contact layer 52 including a Ti film and the noble metal film 54 including a Pt film, as in the first embodiment.

As illustrated in FIG. 16A, the noble metal oxide film 88 comprised of a PtOₓ film is then formed on the noble metal film 54. The noble metal oxide film 88 is included in the lower electrode layer of the resistance storage element. The noble metal oxide film 88 may be an iridium oxide (IrOₓ) film or a ruthenium oxide (RuOₓ) film instead of a PtOₓ film.

As illustrated in FIG. 16B, sputtering or any other suitable method is then used to form the transition metal film 46 including an Ni film on the noble metal oxide film 88. In this process, by carrying out the deposition of the film while heating the entire structure, a layer deposited in an initial stage of the deposition of the transition metal film 46 including an Ni film is oxidized, and a transition metal oxide film 48b including an NiOₓ film is formed at the interface between the transition metal film 46 and the noble metal oxide film 88. The heated film deposition, however, may degrade the flatness of the transition metal film 46. To avoid the problem, it is desirable to carry out the film deposition at room temperature. When the film deposition is carried out at room temperature, a significantly thin transition metal oxide film 48b is formed at the interface between the transition metal film 46 and the noble metal oxide film 88. The transition metal film 46 is formed in an atmosphere without oxygen or any other oxidizing gases, as in the first embodiment.

Heat treatment is then carried out at a temperature within a range from 200 to 750° C., more preferably from 300 to 500° C., for example, in an inert gas atmosphere or a mixed gas atmosphere containing an inert gas and an oxidizing gas. A specific heat treatment condition can be the same as any of the first to third heat treatment conditions in the first embodiment. The heat treatment causes oxygen contained in the noble metal oxide film 88 to be supplied to the transition metal film 46 so as to oxidize the transition metal film 46 into the transition metal oxide film 48 in the resistance storage layer, as illustrated in FIG. 16C. As the noble metal oxide film 88 is reduced, a noble metal film 90 containing the noble metal contained in the noble metal oxide film 88 is formed in the upper portion of the noble metal oxide film 88. While FIG. 16C illustrates a case where part of the transition metal film 46 is left on the transition metal oxide film 48, the heat treatment condition may be adjusted as appropriate to oxidize the entire transition metal film 46.

As described above, oxygen contained in the noble metal oxide film 88 that forms the lower electrode layer of the resistance storage element may be supplied to the transition metal film 46 to oxidize the transition metal film 46 into the transition metal oxide film 48 that forms the resistance storage layer. In this case as well, the thus formed transition metal oxide film 48 has a relatively small film thickness of, for example, 10 nm or smaller and good film thickness uniformity, whereby a resistance storage element operable at low voltage and current levels can be provided.

The composition ratio of the oxygen of the thus formed transition metal oxide film 48 is lower than that in the stoichiometric composition, and the oxygen concentration decreases in the direction from the lower electrode layer toward the upper electrode layer.

A conductive film 92 is then formed on the remaining transition metal film 46, as illustrated in FIG. 16D. Alternatively, the noble metal oxide film 58 may be formed on the transition metal film 46, and then oxygen contained in the noble metal oxide film 58 may be supplied to the transition metal film 46 to further oxidize the remaining transition metal film 46, as in the first embodiment.

As described in the present embodiment, oxygen contained on the noble metal oxide film 88 may be supplied to the transition metal film 46 to oxidize the transition metal film 46 into the transition metal oxide film 48.

[Variation]

The present invention is not limited to the above embodiments, but a variety of changes can be made thereto.

For example, while the description has been made of the case where the transition metal film 46 is made of Ni and the transition metal oxide film 48 containing NiOₓ is formed in the above embodiments, the transition metal film 46 is not necessarily made of Ni. A variety of transition metals can be used as the material of the transition metal film 46 as appropriate to form the transition metal oxide film 48 made of the oxides of the transition metals. For example, the transition metal film 46 may be made of Ti, and the transition metal oxide film 48 made of TiOₓ may be formed.

While the description has been made of the case where the noble metal oxide film 58 formed on the transition metal film 46 is made of PtOₓ in the above embodiments, the noble metal oxide film 58 is not necessarily made of PtOₓ, but a variety of noble metal oxides can be used as appropriate. For example, the noble metal oxide film 58 can be made of IrOₓ, RuOₓ, or other noble metal oxides.

While the description has been made of the case where the noble metal film 54 in the lower electrode layer 44 is made of Pt in the above embodiments, the noble metal film 54 is not necessarily made of Pt, but a variety of noble metals can be used as appropriate. For example, the noble metal film 54 can be made of Ir, Ru, or any other suitable noble metal. Further, the lower electrode layer 44 is not necessarily made of a noble metal, but a variety of conductive materials can be used as appropriate. For example, the lower electrode layer 44 can be made of a transition metal, a transition metal nitride, or any other suitable metal or compound.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method for manufacturing a resistance storage element comprising:
forming a lower electrode layer over a semiconductor substrate;
forming a transition metal film over the lower electrode layer;
forming an upper electrode layer on the transition metal film, the upper electrode layer including a noble metal oxide film; and
supplying oxygen contained in the noble metal oxide film to the transition metal film to oxidize the transition metal film so as to form a resistance storage layer including a transition metal oxide film.

2. The method for manufacturing a resistance storage element according to claim 1, wherein
while forming the resistance storage layer, a noble metal film is formed between the transition metal oxide film and the noble metal oxide film, the noble metal film containing the same type of noble metal as contained in the noble metal oxide film.

3. The method for manufacturing a resistance storage element according to claim 1,
wherein the transition metal oxide film is formed by oxidizing entire of the transition metal film.

4. The method for manufacturing a resistance storage element according to claim 1,
wherein the transition metal oxide film is formed by oxidizing part of the transition metal film, and a remaining transition metal film is left between the transition metal oxide film and the lower electrode layer.

5. The method for manufacturing a resistance storage element according to claim 1,
wherein at least part of the noble metal oxide film changes to a noble metal film.

6. The method for manufacturing a resistance storage element according to claim 1, further comprising:
forming a conductive film on the noble metal oxide film, the conductive film containing a material less oxidizable than a material of the transition metal film.

7. The method for manufacturing a resistance storage element according to claim 6,
wherein the conductive film contains a noble metal.

8. The method for manufacturing a resistance storage element according to claim 1,
wherein the noble metal oxide film is crystallized.

9. The method for manufacturing a resistance storage element according to claim 8,
wherein the noble metal oxide film is formed while heating the resistance storage element to a temperature of 350° C. or lower.

10. The method for manufacturing a resistance storage element according to claim 1,
wherein the noble metal oxide film is formed by oxidizing the surface of the transition metal film in an atmosphere containing an oxidizing gas.

11. The method for manufacturing a resistance storage element according to claim 10,
wherein the noble metal oxide film is formed while heating the resistance storage element to a temperature of 350° C. or lower.

12. A method for manufacturing a resistance storage element comprising:
forming a lower electrode layer over a semiconductor substrate, the lower electrode layer including a noble metal oxide film;
forming a transition metal film on the noble metal oxide film;
supplying oxygen contained in the noble metal oxide film to the transition metal film to oxidize the transition metal film so as to form a resistance storage layer including a transition metal oxide film; and
forming an upper electrode layer over the resistance storage layer.

13. The method for manufacturing a resistance storage element according to claim 12,
wherein the transition metal film is oxidized by heat treatment.

14. The method for manufacturing a resistance storage element according to claim 13,
wherein the temperature at which the heat treatment is carried out ranges from 200° C. to 750° C.

15. The method for manufacturing a resistance storage element according to claim 14,
wherein the temperature at which the heat treatment is carried out ranges from 300° C. to 500° C.

16. The method for manufacturing a resistance storage element according to claim 13,
wherein the heat treatment is carried out in an inert gas atmosphere or a mixed gas atmosphere containing an inert gas and an oxidizing gas.

17. The method for manufacturing a resistance storage element according to claim 13,
wherein the composition ratio of the oxygen of the transition metal oxide film is not stoichiometrically balanced.

18. A resistance storage element comprising:
a lower electrode layer;
a resistance storage layer formed over the lower electrode layer, the resistance storage layer including a transition metal oxide film which is not stoichiometrically balanced; and
an upper electrode layer formed over the resistance storage layer.

19. The resistance storage element according to claim 18,
wherein an oxygen concentration in the transition metal oxide film decreases in the direction from the upper electrode layer toward the lower electrode layer.

20. The resistance storage element according to claim 18,
wherein an oxygen concentration in the transition metal oxide film decreases in the direction from the lower electrode layer toward the upper electrode layer.
